(19) United States
(12) Patent Application Publication
(10) Pub. No.: US 2026/0100778 A1
(43) Pub. Date: Apr. 9, 2026

(54) TECHNIQUES FOR A TWO-SIDED MODEL DEPLOYED AT A USER EQUIPMENT AND A NETWORK EQUIPMENT

(71) Applicant: Lenovo (United States) Inc., Morrisville, NC (US)

(72) Inventors: Vahid Pourahmadi, München (DE); Vijay Nangia, Woodridge, IL (US); Venkata Srinivas Kothapalli, Ottawa (CA); Ahmed Hindy, Aurora, IL (US)

(21) Appl. No.: 18/906,005

(22) Filed: Oct. 3, 2024

(51) Int. Cl. H04L 1/00; H03M 13/00; H04W 24/02

(52) U.S. Cl. CPC H04L 1/0007; H03M 13/616; H04W 24/02

(57) ABSTRACT

Various aspects of the present disclosure relate to techniques for a two-sided model deployed at a user equipment and network equipment. An apparatus includes an encoder to receive input data and transmit encoded output data from the encoder to a decoder comprised in a second apparatus. The apparatus is configured to provide the input data to the encoder to generate the encoded output data, wherein a size of the encoded output data is dependent on the input data provided to the encoder and transmit the encoded output data to the decoder.

### TECHNICAL FIELD

The present disclosure relates to wireless communications, and more specifically to techniques for a two-sided model deployed at a user equipment (UE) and network equipment, e.g., a gNB.

### BACKGROUND

A wireless communications system may include one or multiple network communication devices, such as base stations, which may support wireless communications for one or multiple user communication devices, which may be otherwise known as UE, or other suitable terminology. The wireless communications system may support wireless communications with one or multiple user communication devices by utilizing resources of the wireless communication system (e.g., time resources (e.g., symbols, slots, subframes, frames, or the like) or frequency resources (e.g., subcarriers, carriers, or the like). Additionally, the wireless communications system may support wireless communications across various radio access technologies including third generation (3G) radio access technology, fourth generation (4G) radio access technology, fifth generation (5G) radio access technology, among other suitable radio access technologies beyond 5G (e.g., sixth generation (6G)).

### SUMMARY

An article “a” before an element is unrestricted and understood to refer to “at least one” of those elements or “one or more” of those elements. The terms “a,” “at least one,” “one or more,” and “at least one of one or more” may be interchangeable. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on. Further, as used herein, including in the claims, a “set” may include one or more elements.

In some implementations, an apparatus includes an encoder to receive input data and transmit encoded output data from the encoder to a decoder comprised in a second apparatus. The apparatus is configured to provide the input data to the encoder to generate the encoded output data, wherein a size of the encoded output data is dependent on the input data provided to the encoder and transmit the encoded output data to the decoder.

In some implementations, an apparatus includes a decoder and is configured to receive encoded input data and decoder assistance information indicating a size of the encoded input data from a second apparatus and provide the encoded input data and the decoder assistance information to the decoder to generate decoded data.

### BRIEF DESCRIPTION OF THE DRAWINGS

FIG. 1A illustrates an example of a wireless communications system in accordance with aspects of the present disclosure.

FIG. 1B illustrates an example of a wireless communications system in accordance with aspects of the present disclosure.

FIG. 2 illustrates an example of a two-sided model in accordance with aspects of the present disclosure.

FIG. 3 illustrates an example of an aperiodic trigger state defining a list of channel state information (CSI) report settings in accordance with aspects of the present disclosure.

FIG. 4 illustrates an example of an aperiodic trigger state indicating the resource set and quasi-colocation (QCL) information in accordance with aspects of the present disclosure.

FIG. 5 illustrates an example of a radio resource control (RRC) configuration for non-zero power (NZP)-CSI-reference signal (RS) resource and a CSI-IM-resource in accordance with aspects of the present disclosure.

FIG. 6 illustrates an example of partial CSI omission for physical uplink shared channel (PUSCH)-based CSI in accordance with aspects of the present disclosure.

FIG. 7 illustrates an example of a structure of a two-sided model in accordance with aspects of the present disclosure.

FIG. 8 illustrates an example of a modified structure of a two-sided model in accordance with aspects of the present disclosure.

FIG. 9 illustrates an example of a mask generator block in accordance with aspects of the present disclosure.

FIG. 10 illustrates an example of a user equipment (UE) in accordance with aspects of the present disclosure.

FIG. 11 illustrates an example of a processor in accordance with aspects of the present disclosure.

FIG. 12 illustrates an example of a network equipment (NE) in accordance with aspects of the present disclosure.

FIG. 13 illustrates a flowchart of method in accordance with aspects of the present disclosure.

FIG. 14 illustrates a flowcharts of method in accordance with aspects of the present disclosure.

### DETAILED DESCRIPTION

Various methods have been proposed to reduce the rate of required feedback in a wireless communication network. One group of methods, usually referred to as AI-based methods, consist of two-sided models with two parts where the first part is deployed at the UE side and the second part is deployed at the gNB side. The UE and gNB sides consist of one or a few neural network (NN) blocks which are trained using data driven approaches. The UE side (the encoder part) is responsible to compute a latent representation of the input data (what needs to be transferred to the gNB) with as low number of bits as possible. Receiving what has been transmitted by the UE side, the gNB side (the decoder part) reconstructs the information intended to be transmitted to the gNB using the received message.

The exact structure of the UE and gNB side model can vary depending on the particular scheme/design, but in general it can be assumed that the encoder consists of a few layers and the output 208 usually is (or can be converted to) a vector z with a certain size, e.g., d. Although the design is such that d is usually smaller than the size of the original input data, it is still not suitable for transmission as it is composed of d real valued numbers. To reduce this overhead, vector z is usually quantized using scaler or vector quantizers and the resulted quantized version is transmitted to the other side. The gNB receives these quantized data, dequantize them if needed, and then use them as the input of the decoder part (gNB-side).

With the described two-sided model structure, the total feedback bits required for transmission of information about each channel measurement is equal to the number of bits required for transmission of the quantized data.

One important property of this scheme is that, after the two-sided model is designed the number of feedback bits is fixed and for any input data, i.e., it produces the same number of bits for transmission.

In practical communication systems, the number of bits that can be used for feedback can be different based on different factors, including number of layers to feedback, bandwidth, and the load of the gNB. To support such cases, usually different encoder/decoder blocks, or different quantizer/de-quantizer blocks are designed and they can be applied in the system based on the requirement.

The important point is that even in these cases, for each setting, the number of feedback bits are still fixed for all input data. It is known, however, that some input samples (some channel realizations) might be easier to compress (e.g., a channel representing a LoS condition) and some input samples might be more complex (e.g., a channel representing a NLoS condition) for compression, i.e., needs more feedback bits. The proposed two-sided model does not have the flexibility of sending different number of feedback bits for different input samples.

This contribution presents an AI-based scheme where the dimension of the encoded data (number of feedback bits) is not fixed but can be adjusted based on the input sample.

It is also noted that although in the above description the CSI-feedback use-case is used to describe the problem setting, the contribution is not limited to this particular use-case, and it is applicable to any case where ML modules are used to generate a “transmitting a message” from a node to another node with an optimized number of bit. This contribution can be similarly applied to make the number of transmitted bit dependent on the content of input-sample as well.

As another example, consider a case that the UE wants to use NN blocks to find a representation of images with reduced overhead for transmission to another device. This contribution helps design NN-Based encoder/decoder models in that the output size of the encoder mode is not fixed for all images, and it can be changed based on the complexity of the input image.

Aspects of the present disclosure are described in the context of a wireless communications system, including, but not limited, to cellular or Wi-Fi networks.

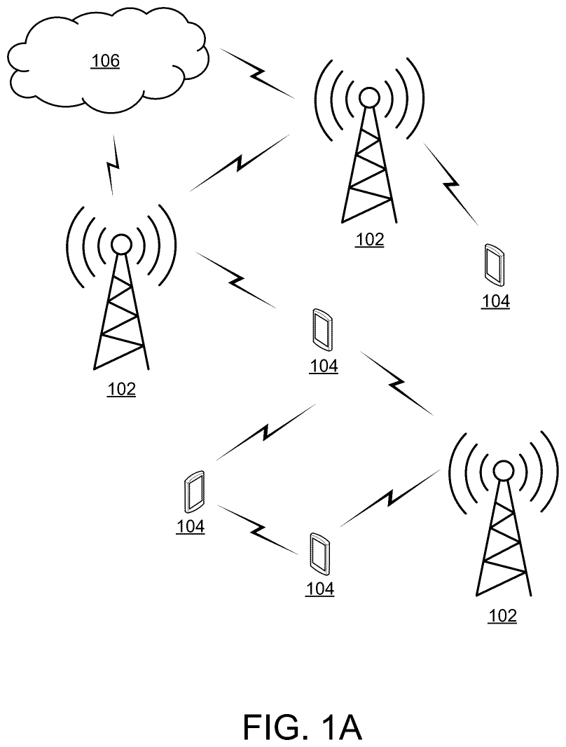

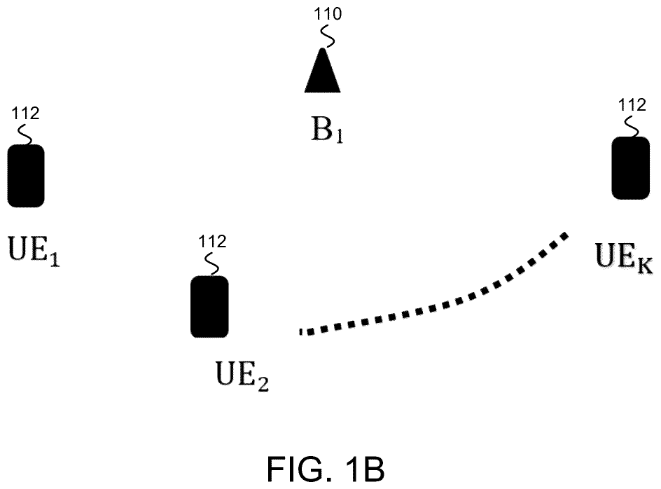

FIG. 1A illustrates an example of a wireless communications system 100 in accordance with aspects of the present disclosure. The wireless communications system 100 may include one or more NE 102, one or more UE 104, and a core network (CN) 106. The wireless communications system 100 may support various radio access technologies. In some implementations, the wireless communications system 100 may be a 4G network, such as an LTE network or an LTE-Advanced (LTE-A) network. In some other implementations, the wireless communications system 100 may be a NR network, such as a 5G network, a 5G-Advanced (5G-A) network, or a 5G ultrawideband (5G-UWB) network. In other implementations, the wireless communications system 100 may be a combination of a 4G network and a 5G network, or other suitable radio access technology including Institute of Electrical and Electronics Engineers (IEEE) 802.11 (Wi-Fi), IEEE 802.16 (WiMAX), IEEE 802.20. The wireless communications system 100 may support radio access technologies beyond 5G, for example, 6G. Additionally, the wireless communications system 100 may support technologies, such as time division multiple access (TDMA), frequency division multiple access (FDMA), or code division multiple access (CDMA), etc.

The one or more NE 102 may be dispersed throughout a geographic region to form the wireless communications system 100. One or more of the NE 102 described herein may be or include or may be referred to as a network node, a base station, a network element, a network function, a network entity, a radio access network (RAN), a NodeB, an eNodeB (eNB), a next-generation NodeB (gNB), or other suitable terminology. An NE 102 and a UE 104 may communicate via a communication link, which may be a wireless or wired connection. For example, an NE 102 and a UE 104 may perform wireless communication (e.g., receive signaling, transmit signaling) over a Uu interface.

An NE 102 may provide a geographic coverage area for which the NE 102 may support services for one or more UEs 104 within the geographic coverage area. For example, an NE 102 and a UE 104 may support wireless communication of signals related to services (e.g., voice, video, packet data, messaging, broadcast, etc.) according to one or multiple radio access technologies. In some implementations, an NE 102 may be moveable, for example, a satellite associated with a non-terrestrial network (NTN). In some implementations, different geographic coverage areas 112 associated with the same or different radio access technologies may overlap, but the different geographic coverage areas may be associated with different NE 102.

The one or more UE 104 may be dispersed throughout a geographic region of the wireless communications system 100. A UE 104 may include or may be referred to as a remote unit, a mobile device, a wireless device, a remote device, a subscriber device, a transmitter device, a receiver device, or some other suitable terminology. In some implementations, the UE 104 may be referred to as a unit, a station, a terminal, or a client, among other examples. Additionally, or alternatively, the UE 104 may be referred to as an Internet-of-Things (IoT) device, an Internet-of-Everything (IoE) device, or machine-type communication (MTC) device, among other examples.

A UE 104 may be able to support wireless communication directly with other UEs 104 over a communication link. For example, a UE 104 may support wireless communication directly with another UE 104 over a device-to-device (D2D) communication link. In some implementations, such as vehicle-to-vehicle (V2V) deployments, vehicle-to-everything (V2X) deployments, or cellular-V2X deployments, the communication link 114 may be referred to as a sidelink. For example, a UE 104 may support wireless communication directly with another UE 104 over a PC5 interface.

An NE 102 may support communications with the CN 106, or with another NE 102, or both. For example, an NE 102 may interface with other NE 102 or the CN 106 through one or more backhaul links (e.g., S1, N2, N2, or network interface). In some implementations, the NE 102 may communicate with each other directly. In some other implementations, the NE 102 may communicate with each other or indirectly (e.g., via the CN 106. In some implementations, one or more NE 102 may include subcomponents, such as an access network entity, which may be an example of an access node controller (ANC). An ANC may communicate with the one or more UEs 104 through one or more other access network transmission entities, which may be referred to as a radio heads, smart radio heads, or transmission-reception points (TRPs).

The CN 106 may support user authentication, access authorization, tracking, connectivity, and other access, routing, or mobility functions. The CN 106 may be an evolved packet core (EPC), or a 5G core (5GC), which may include a control plane entity that manages access and mobility (e.g., a mobility management entity (MME), an access and mobility management functions (AMF)) and a user plane entity that routes packets or interconnects to external networks (e.g., a serving gateway (S-GW), a Packet Data Network (PDN) gateway (P-GW), or a user plane function (UPF)). In some implementations, the control plane entity may manage non-access stratum (NAS) functions, such as mobility, authentication, and bearer management (e.g., data bearers, signal bearers, etc.) for the one or more UEs 104 served by the one or more NE 102 associated with the CN 106.

The CN 106 may communicate with a packet data network over one or more backhaul links (e.g., via an S1, N2, N2, or another network interface). The packet data network may include an application server. In some implementations, one or more UEs 104 may communicate with the application server. A UE 104 may establish a session (e.g., a protocol data unit (PDU) session, or the like) with the CN 106 via an NE 102. The CN 106 may route traffic (e.g., control information, data, and the like) between the UE 104 and the application server using the established session (e.g., the established PDU session). The PDU session may be an example of a logical connection between the UE 104 and the CN 106 (e.g., one or more network functions of the CN 106).

In the wireless communications system 100, the NEs 102 and the UEs 104 may use resources of the wireless communications system 100 (e.g., time resources (e.g., symbols, slots, subframes, frames, or the like) or frequency resources (e.g., subcarriers, carriers)) to perform various operations (e.g., wireless communications). In some implementations, the NEs 102 and the UEs 104 may support different resource structures. For example, the NEs 102 and the UEs 104 may support different frame structures. In some implementations, such as in 4G, the NEs 102 and the UEs 104 may support a single frame structure. In some other implementations, such as in 5G and among other suitable radio access technologies, the NEs 102 and the UEs 104 may support various frame structures (i.e., multiple frame structures). The NEs 102 and the UEs 104 may support various frame structures based on one or more numerologies.

One or more numerologies may be supported in the wireless communications system 100, and a numerology may include a subcarrier spacing and a cyclic prefix. A first numerology (e.g., μ=0) may be associated with a first subcarrier spacing (e.g., 15 kHz) and a normal cyclic prefix. In some implementations, the first numerology (e.g., μ=0) associated with the first subcarrier spacing (e.g., 15 kHz) may utilize one slot per subframe. A second numerology (e.g., μ=1) may be associated with a second subcarrier spacing (e.g., 30 kHz) and a normal cyclic prefix. A third numerology (e.g., μ=2) may be associated with a third subcarrier spacing (e.g., 60 kHz) and a normal cyclic prefix or an extended cyclic prefix. A fourth numerology (e.g., μ=3) may be associated with a fourth subcarrier spacing (e.g., 120 kHz) and a normal cyclic prefix. A fifth numerology (e.g., μ=4) may be associated with a fifth subcarrier spacing (e.g., 240 kHz) and a normal cyclic prefix.

A time interval of a resource (e.g., a communication resource) may be organized according to frames (also referred to as radio frames). Each frame may have a duration, for example, a 10 millisecond (ms) duration. In some implementations, each frame may include multiple subframes. For example, each frame may include 10 subframes, and each subframe may have a duration, for example, a 1 ms duration. In some implementations, each frame may have the same duration. In some implementations, each subframe of a frame may have the same duration.

Additionally or alternatively, a time interval of a resource (e.g., a communication resource) may be organized according to slots. For example, a subframe may include a number (e.g., quantity) of slots. The number of slots in each subframe may also depend on the one or more numerologies supported in the wireless communications system 100. For instance, the first, second, third, fourth, and fifth numerologies (i.e., μ=0, μ=1, μ=2, μ=3, μ=4) associated with respective subcarrier spacings of 15 kHz, 30 kHz, 60 kHz, 120 kHz, and 240 kHz may utilize a single slot per subframe, two slots per subframe, four slots per subframe, eight slots per subframe, and 16 slots per subframe, respectively. Each slot may include a number (e.g., quantity) of symbols (e.g., OFDM symbols). In some implementations, the number (e.g., quantity) of slots for a subframe may depend on a numerology. For a normal cyclic prefix, a slot may include 14 symbols. For an extended cyclic prefix (e.g., applicable for 60 kHz subcarrier spacing), a slot may include 12 symbols. The relationship between the number of symbols per slot, the number of slots per subframe, and the number of slots per frame for a normal cyclic prefix and an extended cyclic prefix may depend on a numerology. It should be understood that reference to a first numerology (e.g., μ=0) associated with a first subcarrier spacing (e.g., 15 kHz) may be used interchangeably between subframes and slots.

In the wireless communications system 100, an electromagnetic (EM) spectrum may be split, based on frequency or wavelength, into various classes, frequency bands, frequency channels, etc. By way of example, the wireless communications system 100 may support one or multiple operating frequency bands, such as frequency range designations FR1 (410 MHz-7.125 GHz), FR2 (24.25 GHz-52.6 GHz), FR3 (7.125 GHz-24.25 GHz), FR4 (52.6 GHz-114.25 GHz), FR4a or FR4-1 (52.6 GHz-71 GHz), and FR5 (114.25 GHz-300 GHz). In some implementations, the NEs 102 and the UEs 104 may perform wireless communications over one or more of the operating frequency bands. In some implementations, FR1 may be used by the NEs 102 and the UEs 104, among other equipment or devices for cellular communications traffic (e.g., control information, data). In some implementations, FR2 may be used by the NEs 102 and the UEs 104, among other equipment or devices for short-range, high data rate capabilities.

FR1 may be associated with one or multiple numerologies (e.g., at least three numerologies). For example, FR1 may be associated with a first numerology (e.g., μ=0), which includes 15 kHz subcarrier spacing; a second numerology (e.g., μ=1), which includes 30 kHz subcarrier spacing; and a third numerology (e.g., μ=2), which includes 60 kHz subcarrier spacing. FR2 may be associated with one or multiple numerologies (e.g., at least 2 numerologies). For example, FR2 may be associated with a third numerology (e.g., μ=2), which includes 60 kHz subcarrier spacing; and a fourth numerology (e.g., μ=3), which includes 120 kHz subcarrier spacing.

FIG. 1B shows a typical wireless network with one gNB represented by node B₁ 110 equipped with M antennas and K UEs 112 denoted by U₁, U₂, . . . , U_{K} each has N antennas.

$${H}_{l}^{k} ( t )$$

denotes the downlink channel at time t over frequency band l, l∈{1, 2, . . . , L}, between B₁ and Uₖ which is a matrix of size N×M with complex entries, i.e.,

$${H}_{l}^{k} ( t ) ∈ {ℂ}^{N \times M} .$$

At time t and frequency band l, it is assumed that the gNB wants to transmit message

$${x}_{l}^{k} ( t )$$

to user Uₖ where k={1, 2, . . . , K} while it uses

$${w}_{l}^{k} ( t ) ∈ {ℂ}^{M \times 1}$$

as the precoding vector. The received signal at Uₖ,

$${y}_{l}^{k} ( t ) ,$$

can be written as:

$${y}_{l}^{k} ( t ) = {H}_{l}^{k} ( t ) {w}_{l}^{k} ( t ) {x}_{l}^{k} ( t ) + {n}_{l}^{k} ( t )$$

where

$${n}_{l}^{k} ( t )$$

represents the noise vector at the receiver.

To improve the achievable rate of the link, the gNB selects

$${w}_{l}^{k} ( t )$$

that maximizes the received SNR or SINR (in case of muti-user transmission). Several schemes have been proposed for good selection of

$${w}_{l}^{k} ( t )$$

where most of them relies on having some knowledge about

$${H}_{l}^{k} ( t )$$

at the node B₁.

The gNB can get knowledge of

$${H}_{l}^{k} ( t )$$

by direct measurement of the channel (e.g., in TDD mode and assuming reciprocity of the channel), or indirectly using the information (e.g. sounding reference signal SRS) that the UE sends to the gNB (e.g., in TDD or FDD mode). In the latter case, a large amount of feedback may be needed to send accurate information about

$${H}_{l}^{k} ( t ) .$$

This becomes particularly important if a large number of antennas or/and large frequency bands are present. See 3GPP TS 38.214, 3GPP TS 38.321, and 3GPP TS 38.331, all incorporated herein by reference.

For simplicity in description, only a single time slot is considered, but the proposed scheme can be further extended to the cases with more than a single time slot. Without loss of generality, therefore,

$${H}_{l}^{k} ( t )$$

is denoted using

$${H}_{l}^{k} .$$

Further, H^{k} is defined as a matrix of size N×M×L which composed by stacking

$${H}_{l}^{k}$$

for all frequency bands, i.e., the entries at H^{k}[n,m,l] is equal to

$${H}_{l}^{k} [ n , m ] .$$

Therefore, sending complete information regarding H^{k}, the UE need to feedback the information about N×M×L complex numbers to the gNB.

Several methods have been proposed trying to reduce the rate of required feedback. A first group of methods include conventional methods which are based on quantization of the measured channel based on a codebook designed in 3GPP.

Another group of methods, usually referred to as AI-based methods, consist of two-sided models with two parts where the first part is deployed at the UE side and the second part is deployed at the gNB side. The UE and gNB sides consist of one or a few NN blocks which are trained using data driven approaches. The UE side (the encoder part) is responsible to compute a latent representation of the input data (what needs to be transferred to the gNB) with as low number of bits as possible. Receiving what has been transmitted by the UE side, the gNB side (the decoder part) reconstructs the information intended to be transmitted to the gNB using the received message.

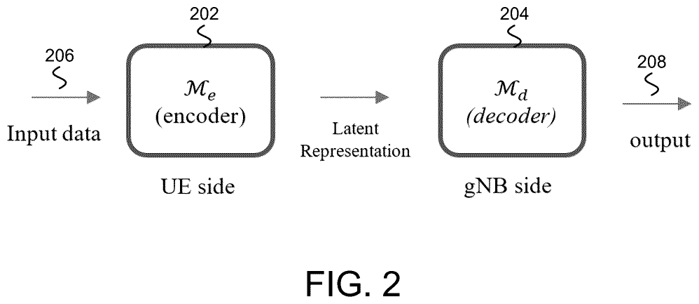

FIG. 2 depicts a high-level structure of a two-sided model with NN-based UE and gNB sides referred to here as Mₑ (encoding model) 202 and M_{d} (decoding model) 204, respectively. The input data 206 of the model is based on the channel measurement, which can be for example, raw channel measurement, or eigenvectors associated to the measured channel.

The exact structure of the UE and gNB side model can vary depending on the particular scheme/design but in general it is assumed that the encoder consists of a few layers and the output 208 usually is (or can be converted to) a vector z with a certain size, e.g., d. Although the design is such that d is usually smaller that the size of the original input data, it is still not suitable for transmission as it is composed of d real valued numbers. To reduce this overhead, vector z is usually quantized using scaler or vector quantizers and the resulted quantized version is transmitted to the other side. The gNB receives these quantized data, dequantize them if needed, and then use them as the input of the decoder part (gNB-side).

With the described two-sided model structure, the total feedback bits required for transmission of information about each channel measurement is equal to the number of bits required for transmission of the quantized data.

One important property of this scheme is that, after the two-sided model is designed, the number of feedback bits is fixed and for any input data, i.e., it produces the same number of bits for transmission.

In practical communication systems, the number of bits that can be used for feedback can be different based on different factors including number of layers to feedback, bandwidth, and the load of the gNB. To support such cases, usually different encoder/decoder blocks, or different quantizer/de-quantizer blocks are designed and they can be applied in the system based on the requirement.

The important point is that even in these cases, for each setting, the number of feedback bits are still fixed for all input data. It is known, however, that some input samples (some channel realizations) might be easier to compress (e.g., a channel representing a LoS condition) and some input samples might be more complex (e.g., a channel representing a NLoS condition) for compression, i.e., needs more feedback bits. The proposed two-sided model does not have the flexibility of sending different number of feedback bits for different input samples.

This contribution presents an AI-based scheme where the dimension of the encoded data (number of feedback bits) is not fixed and can be adjusted based on the input sample.

It is also noted that although in the above description the CSI-feedback use-case is used to describe the problem setting, the contribution is not limited to this particular use-case, and it is appliable to any case where ML modules are used to generation a “transmitting a message” from a node to another node with an optimized number of bit. This contribution can be similarly applied there to make the number of transmitted bit dependent on the content of input-sample as well.

As another example, consider a case that the UE wants to use NN blocks to find a representation of images with reduced overhead for transmission to another devices. This contribution helps on designing NN-Based encoder/decoder models that the output size of the encoder mode is not fixed for all images, and it can be changed based on the complexity of the input image.

As explained, there are a few conventional schemes for compressing the channel information before sending back to the gNB. It is noted that, in some of the conventional schemes, the number of feedback bits, can be different for different measurements, this happens by skipping transmission of some of the entries which has small values. See 3GPP TS 38.214. A summary is provided below, namely on how to define the CSI Codebooks and then how to feedback the resulted bits.

For NR Rel. 15 Type-II Codebook, assume the gNB is equipped with a two-dimensional (“2D”) antenna array with N₁, N₂ antenna ports per polarization placed horizontally and vertically and communication occurs over N₃ PMI sub-bands. A PMI sub-band consists of a set of resource blocks, each resource block consisting of a set of subcarriers. In such case, 2N₁N₂ CSI-reference signal (“RS”) ports are utilized to enable DL channel estimation with high resolution for NR Type-II codebook. To reduce the UL feedback overhead, a Discrete Fourier transform (“DFT”)-based CSI compression of the spatial domain is applied to L dimensions per polarization, where L<N₁N₂. The magnitude and phase values of the linear combination coefficients for each sub-band are fed back to the gNB as part of the CSI report. The 2N₁N₂×N₃ codebook per layer takes on the form

$$W = {W}_{1} {W}_{2} ,$$

where W₁ is a 2N₁N₂×2L block-diagonal matrix (L<N₁N₂) with two identical diagonal blocks, i.e.,

$${W}_{1} = [ \begin{matrix}B & 0 \\ 0 & B\end{matrix} ] ,$$

and B is an N₁N₂×L matrix with columns drawn from a 2D oversampled DFT matrix, as follows.

$${u}_{m} = [ \begin{matrix}1 & {e}^{j \frac{2 π m}{{O}_{2} {N}_{2}}} & … & {e}^{j \frac{2 π m ( {N}_{2} - 1 )}{{O}_{2} {N}_{2}}}\end{matrix} ] ,$$

$${v}_{l , m} = {[ \begin{matrix}{u}_{m} & {e}^{j \frac{2 π m}{{O}_{2} {N}_{2}}} & … & {e}^{j \frac{2 π l ( {N}_{1} - 1 )}{{O}_{1} {N}_{1}}} {u}_{m}\end{matrix} ]}^{T} ,$$

$$B = [ \begin{matrix}{v}_{{l}_{0} , {m}_{0}} & {v}_{{l}_{1} , {m}_{1}} & … & {v}_{{l}_{L - 1} , {m}_{L - 1}}\end{matrix} ] ,$$

$${l}_{i} = {O}_{1} {n}_{1}^{( i )} + {q}_{1} , 0 \leq {n}_{1}^{( i )} < {N}_{I} , 0 \leq {q}_{1} < {O}_{1} ,$$

$${m}_{i} = {O}_{2} {n}_{2}^{( i )} + {q}_{2} , 0 \leq {n}_{2}^{( i )} < {N}_{2} , 0 \leq {q}_{2} < {O}_{2} ,$$

where the superscript ^{T} denotes a matrix transposition operation. Note that O₁, O₂ oversampling factors are assumed for the 2D DFT matrix from which matrix B is drawn. Note that W₁ is common across all layers. W₂ is a 2L×N₃ matrix, where the i^{th} column corresponds to the linear combination coefficients of the 2L beams in the i^{th} sub-band. Only the indices of the L selected columns of B are reported, along with the oversampling index taking on O₁O₂ values. Note that W₂ are independent for different layers.

For NR Rel. 15 Type-II Port Selection codebook, in one embodiment, only K (where K≤2N₁N₂) beamformed CSI-RS ports are utilized in DL transmission, in order to reduce complexity. The K×N₃ codebook matrix per layer takes on the form (See 3GPP TS 38.214):

$$W = {W}_{1}^{PS} {W}_{2} .$$

Here, W₂ follow the same structure as the conventional NR Rel. 15 Type-II Codebook and are layer specific.

$${W}_{1}^{PS}$$

is a K×2L block-diagonal matrix with two identical diagonal blocks, i.e.,

$${W}_{1}^{PS} = [ \begin{matrix}E & 0 \\ 0 & E\end{matrix} ] ,$$

and E is a

$$\frac{K}{2} \times L$$

matrix whose columns are standard unit vectors, as follows:

$$E = [ \begin{matrix}{e}_{mod ( {m}_{PS} {d}_{PS} , K / 2 )}^{( K / 2 )} & {e}_{mod ( {m}_{PS} {d}_{PS} + 1 , K / 2 )}^{( K / 2 )} & … & {e}_{mod ( {m}_{PS} {d}_{PS} + L - 1 , K / 2 )}^{( K / 2 )}\end{matrix} ] ,$$

where

$${e}_{i}^{( K )}$$

is a standard unit vector with a 1 at the i^{th} location. Here d_{PS} is an RRC parameter which takes on the values {1,2,3,4} under the condition d_{PS}≤min(K/2, L), whereas m_{PS} takes on the values

$$\{ 0 , … , ⌈ \frac{K}{2 {d}_{P S}} ⌉ - 1 \}$$

and is reported as part of the UL CSI feedback overhead. W₁ is common across all layers.

For K=16, L-4 and d_{PS}=1, the 8 possible realizations of E corresponding to m_{PS}={0, 1, . . . , 7} are as follows:

$$[ \begin{matrix}1 & 0 & 0 & 0 \\ 0 & 1 & 0 & 0 \\ 0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0\end{matrix} ] , [ \begin{matrix}0 & 0 & 0 & 0 \\ 1 & 0 & 0 & 0 \\ 0 & 1 & 0 & 0 \\ 0 & 0 & 1 & 0 \\ 0 & 0 & 0 & 1 \\ 0 & 0 & 0 & 0 \\ 0 & 0 & 0 & 0 \\ 0 & 0 & 0 & 0\end{matrix} ] , [ \begin{matrix}0 & 0 & 0 & 0 \\ 0 & 0 & 0 & 0 \\ 1 & 0 & 0 & 0 \\ 0 & 1 & 0 & 0 \\ 0 & 0 & 1 & 0 \\ 0 & 0 & 0 & 1 \\ 0 & 0 & 0 & 0 \\ 0 & 0 & 0 & 0\end{matrix} ] , [ \begin{matrix}0 & 0 & 0 & 0 \\ 0 & 0 & 0 & 0 \\ 0 & 0 & 0 & 0 \\ 1 & 0 & 0 & 0 \\ 0 & 1 & 0 & 0 \\ 0 & 0 & 1 & 0 \\ 0 & 0 & 0 & 1 \\ 0 & 0 & 0 & 0\end{matrix} ] , [ \begin{matrix}0 & 0 & 0 & 0 \\ 0 & 0 & 0 & 0 \\ 0 & 0 & 0 & 0 \\ 0 & 0 & 0 & 0 \\ 1 & 0 & 0 & 0 \\ 0 & 1 & 0 & 0 \\ 0 & 0 & 1 & 0 \\ 0 & 0 & 0 & 1\end{matrix} ] ,$$

$$[ \begin{matrix}0 & 0 & 0 & 1 \\ 0 & 0 & 0 & 0 \\ 0 & 0 & 0 & 0 \\ 0 & 0 & 0 & 0 \\ 0 & 0 & 0 & 0 \\ 1 & 0 & 0 & 0 \\ 0 & 1 & 0 & 0 \\ 0 & 0 & 1 & 0\end{matrix} ] , [ \begin{matrix}0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0 \\ 1 & 0 & 0 & 0 \\ 0 & 1 & 0 & 0\end{matrix} ] , [ \begin{matrix}0 & 1 & 0 & 0 \\ 0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0 \\ 1 & 0 & 0 & 0\end{matrix} ] .$$

When d_{PS}=2, the 4 possible realizations of E corresponding to m_{PS}={0,1,2,3} are as follows:

$$[ \begin{matrix}1 & 0 & 0 & 0 \\ 0 & 1 & 0 & 0 \\ 0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0\end{matrix} ] , [ \begin{matrix}0 & 0 & 0 & 0 \\ 0 & 0 & 0 & 0 \\ 1 & 0 & 0 & 0 \\ 0 & 1 & 0 & 0 \\ 0 & 0 & 1 & 0 \\ 0 & 0 & 0 & 1 \\ 0 & 0 & 0 & 0 \\ 0 & 0 & 0 & 0\end{matrix} ] , [ \begin{matrix}0 & 0 & 0 & 0 \\ 0 & 0 & 0 & 0 \\ 0 & 0 & 0 & 0 \\ 0 & 0 & 0 & 0 \\ 1 & 0 & 0 & 0 \\ 0 & 1 & 0 & 0 \\ 0 & 0 & 1 & 0 \\ 0 & 0 & 0 & 1\end{matrix} ] , [ \begin{matrix}0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0 \\ 1 & 0 & 0 & 0 \\ 0 & 1 & 0 & 0\end{matrix} ] .$$

When d_{PS}=3, the 3 possible realizations of E corresponding of m_{PS}={0,1,2} are as follows:

$$[ \begin{matrix}1 & 0 & 0 & 0 \\ 0 & 1 & 0 & 0 \\ 0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0\end{matrix} ] , [ \begin{matrix}0 & 0 & 0 & 0 \\ 0 & 0 & 0 & 0 \\ 0 & 0 & 0 & 0 \\ 1 & 0 & 0 & 0 \\ 0 & 1 & 0 & 0 \\ 0 & 0 & 1 & 0 \\ 0 & 0 & 0 & 1 \\ 0 & 0 & 0 & 0\end{matrix} ] , [ \begin{matrix}0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0 \\ 1 & 0 & 0 & 0 \\ 0 & 1 & 0 & 0\end{matrix} ] .$$

When d_{PS}=4, the 2 possible realizations of E corresponding of m_{PS}={0,1} are as follows:

$$[ \begin{matrix}1 & 0 & 0 & 0 \\ 0 & 1 & 0 & 0 \\ 0 & 0 & 1 & 0 \\ 0 & 0 & 0 & 1 \\ 0 & 0 & 0 & 0 \\ 0 & 0 & 0 & 0 \\ 0 & 0 & 0 & 0 \\ 0 & 0 & 0 & 0\end{matrix} ] , [ \begin{matrix}0 & 0 & 0 & 0 \\ 0 & 0 & 0 & 0 \\ 0 & 0 & 0 & 0 \\ 0 & 0 & 0 & 0 \\ 1 & 0 & 0 & 0 \\ 0 & 1 & 0 & 0 \\ 0 & 0 & 1 & 0 \\ 0 & 0 & 0 & 1\end{matrix} ] .$$

To summarize, in one embodiment, m_{PS} parametrizes the location of the first 1 in the first column of E, whereas d_{PS} represents the row shift corresponding to different values of m_{PS}.

In one embodiment, NR Rel. 15 Type-I codebook is the baseline codebook for NR, with a variety of configurations. The most common utility of Type-I codebook is a special case of NR Type-II codebook with L=1 for RI=1,2, wherein a phase coupling value is reported for each sub-band, i.e., W₂ is 2×N₃, with the first row equal to [1, 1, . . . , 1] and the second row equal to [e^{j2πØ}^{₀}, . . . , e^{j2πØ}^{_{N3-1}}]. Under specific configurations, φ₀=φ₁ . . . =φ, i.e., wideband reporting. For RI>2 different beams are used for each pair of layers. Obviously, NR Type-I codebook can be depicted as a low-resolution version of NR Type-II codebook with spatial beam selection per layer-pair and phase combining only (See R1-1709232, Samsung et al., “WF on Type I and II CSI codebooks,” Hangzhou, China, incorporated herein by reference).

Regarding NR Rel. 161 Type-II codebook, in one embodiment, assume the gNB is equipped with a two-dimensional (2D) antenna array with N₁, N₂ antenna ports per polarization placed horizontally and vertically and communication occurs over N₃ PMI subbands. A PMI subband consists of a set of resource blocks, each resource block consisting of a set of subcarriers. In such case, 2N₁N₂N₃ CSI-RS ports are utilized to enable DL channel estimation with high resolution for NR Rel. 16 Type-II codebook. In order to reduce the UL feedback overhead, a Discrete Fourier transform (DFT)-based CSI compression of the spatial domain is applied to L dimensions per polarization, where L<N₁N₂. Similarly, additional compression in the frequency domain is applied, where each beam of the frequency-domain precoding vectors is transformed using an inverse DFT matrix to the delay domain, and the amplitude and phase values of a subset of the delay-domain coefficients are selected and fed back to the gNB as part of the CSI report. The 2N₁N₂×N₃ codebook per layer takes on the form (See 3GPP TS 38.214):

$$W = {W}_{1} {\tilde{W}}_{2} {W}_{f}^{H} ,$$

where W₁ is a 2N₁N₂×2L block-diagonal matrix (L<N₁N₂) with two identical diagonal blocks, i.e.,

$${W}_{1} = [ \begin{matrix}B & 0 \\ 0 & B\end{matrix} ] ,$$

and B is an N₁N₂×L matrix with columns drawn from a 2D oversampled DFT matrix, as follows:

$${u}_{m} = [ \begin{matrix}1 & {e}^{j \frac{2 π m}{{O}_{2} {N}_{2}}} & … & {e}^{j \frac{2 π m ( {N}_{2} - 1 )}{{O}_{2} {N}_{2}}}\end{matrix} ] ,$$

$${v}_{l , m} = {[ \begin{matrix}{u}_{m} & {e}^{j \frac{2 π l}{{O}_{1} {N}_{1}}} {u}_{m} & … & {e}^{j \frac{2 π l ( {N}_{1} - 1 )}{{O}_{1} {N}_{1}}} {u}_{m}\end{matrix} ]}^{T} ,$$

$$B = [ \begin{matrix}{v}_{{l}_{0} , {m}_{0}} & {v}_{{l}_{1} , {m}_{1}} & … & {v}_{{l}_{L - 1} , {m}_{L - 1}}\end{matrix} ] ,$$

$${l}_{i} = {O}_{1} {n}_{1}^{( i )} + {q}_{1} , 0 \leq {n}_{1}^{( i )} < {N}_{1} , 0 \leq {q}_{1} < {O}_{1} ,$$

$${m}_{i} = {O}_{2} {n}_{2}^{( i )} + {q}_{2} , 0 \leq {n}_{2}^{( i )} < {N}_{2} , 0 \leq {q}_{2} < {O}_{2} ,$$

where the superscript ^{T} denotes a matrix transposition operation. Note that O₁, O₂ oversampling factors are assumed for the 2D DFT matrix from which matrix B is drawn. Note that W₁ is common across all layers. W_{f} is an N₃×M matrix (M<N₃) with columns selected from a critically sampled size-N₃ DFT matrix, as follows:

$${W}_{f} = [ \begin{matrix}{f}_{{k}_{0}} & {f}_{{k}_{1}} & … & {f}_{{k}_{{M}^{′} - 1}}\end{matrix} ] , 0 \leq {k}_{i} < {N}_{3} - 1 ,$$

$${f}_{k} = {[ \begin{matrix}1 & {e}^{- j \frac{2 π k}{{N}_{3}}} & … & {e}^{- j \frac{2 π k ( {N}_{3} - 1 )}{{N}_{3}}}\end{matrix} ]}^{T} .$$

The indices of the L selected columns of B are reported, along with the oversampling index taking on O₁O₂ values. Similarly, for W_{F}, only the indices of the M selected columns out of the predefined size-N₃ DFT matrix are reported. In the sequel the indices of the M dimensions are referred as the selected Frequency Domain (“FD”) basis indices. Hence, L, M represent the equivalent spatial and frequency dimensions after compression, respectively. Finally, the 2L×M matrix \tilde{W}₂ represents the linear combination coefficients (“LCCs”) of the spatial and frequency DFT-basis vectors. Both \tilde{W}₂, W_{f} are selected independent for different layers. Magnitude and phase values of an approximately β fraction of the 2LM available coefficients are reported to the gNB (β<1) as part of the CSI report. Coefficients with zero magnitude are indicated via a per-layer bitmap. Since all coefficients reported within a layer are normalized with respect to the coefficient with the largest magnitude (strongest coefficient), the relative value of that coefficient is set to unity, and no magnitude or phase information is explicitly reported for this coefficient. Only an indication of the index of the strongest coefficient per layer is reported. Hence, for a single-layer transmission, magnitude and phase values of a maximum of ┌2βLM┐−1 coefficients (along with the indices of selected L, M DFT vectors) are reported per layer, leading to significant reduction in CSI report size, compared with reporting 2N₁N₂×N₃−1 coefficients' information.

Regarding NR Rel. 16 Type II Port Selection Codebook, only K (where K≤2N₁N₂) beamformed CSI-RS ports are utilized in DL transmission, to reduce complexity. The K×N₃ codebook matrix per layer takes on the form (See 3GPP TS 38.214):

$$W = {W}_{1}^{PS} {\tilde{W}}_{2} {W}_{f}^{H}$$

Here, \tilde{W}₂ and W₃ follow the same structure as the conventional NR Rel. 16 Type-II Codebook, where both are layer specific. The matrix

$${W}_{1}^{PS}$$

is a K×2L block-diagonal matrix with the same structure as that in the NR Rel. 15 Type-II Port Selection Codebook.

Rel. 17 Type-II Port Selection codebook follows a similar structure as that of Rel. 15 and Rel. 16 port-selection codebooks, as follows:

$${W}_{l} = {\overline{W}}_{1}^{PS} {\tilde{W}}_{2 , l} {W}_{f , l}^{H} .$$

However, unlike Rel. 15 and Rel. 16 Type-II port-selection codebooks, the port-selection matrix

$${\overline{W}}_{1}^{PS}$$

supports free selection of the K ports, or more precisely the K/2 ports per polarization out of the N₁N₂ CSI-RS ports per polarization, i.e.,

$$⌈ {log}_{2} ( \begin{matrix}{N}_{1} {N}_{2} \\ K / 2\end{matrix} ) ⌉ bits$$

are used to identify the K/2 selected ports per polarization, wherein this selection is common across all layers. Here, \tilde{W}_{2,l} and W_{f,l} follow the same structure as the conventional NR Rel. 16 Type-II Codebook, however M is limited to 1,2 only, with the network configuring a window of size N={2,4} for M=2. Moreover, the bitmap is reported unless β=1 and the UE reports all the coefficients for a rank up to a value of two.

For Rel-18 potential Type-II codebook, the time-domain corresponding to slots is further compressed via DFT-based transformation, wherein the codebook is in the following form:

$${W}_{l} = {W}_{1} {{\tilde{W}}_{2 , l} ( {W}_{f , l} ⊗ {W}_{d , l} )}^{H} ,$$

where W₁, W_{f,l} follow the same structure as Rel-16 Type-II codebook, W_{d,l} is an N₄×Q matrix (Q≤N₄) with columns selected from a critically-sampled size-N₄ DFT matrix, as follows:

$${W}_{d , l} = [ \begin{matrix}{d}_{{q}_{0}} & {d}_{{q}_{1}} & … & {d}_{{q}_{Q - 1}}\end{matrix} ] , 0 \leq {q}_{i} \leq {N}_{4} - 1 ,$$

$${d}_{q} = {[ \begin{matrix}1 & {e}^{- j \frac{2 π q}{{N}_{4}}} & … & {e}^{- j \frac{2 π q ( {N}_{4} - 1 )}{{N}_{4}}}\end{matrix} ]}^{T} .$$

Only the indices of the Q selected columns of W_{d,l} are reported. Note that W_{d,l} may be layer specific, e.g., W_{d,1}≠W_{d,2}, or layer common, i.e., W_{d,1}= . . . =W_{d,RI}, where RI corresponds to the total number of layers, and the operator ⊗ corresponds to a Kronecker matrix product. Here, \tilde{W}_{2,l} is a 2L×MQ sized matrix with layer-specific entries representing the LCCs corresponding to the spatial-domain, frequency-domain and time-domain DFT-basis vectors. Thereby, a size 2L×MQ bitmap may need to be reported associated with Rel-18 Type-II codebook.

Regarding codebook reporting, in one embodiment, the codebook report is partitioned into two parts based on the priority of information reported. Each part is encoded separately (Part 1 has a possibly higher code rate). Below are parameters for NR Rel. 16 Type-II codebook (See 3GPP TS 38.214):

$$Part 1 : RI + CQI + Total number of coefficients$$

$$Part 2 : SD basis indicator + FD basis indicator / layer + Bitmap / layer + Coefficient Amplitude info / layer + Coefficient Phase info / layer + Strongest coefficient indicator / layer$$

Furthermore, in one embodiment, Part 2 CSI can be decomposed into sub-parts each with different priority (higher priority information listed first). Such partitioning is required to allow dynamic reporting size for codebook based on available resources in the UL phase (See 3GPP TS 38.214).

Also Type-II codebook, in one embodiment, is based on aperiodic CSI reporting, and only reported in PUSCH via DCI triggering (one exception). Type-I codebook can be based on periodic CSI reporting (PUCCH) or semi-persistent CSI reporting (PUSCH or PUCCH) or aperiodic reporting (PUSCH).

Note that multiple CSI reports may be transmitted with different priorities, as shown in Table 1. Additionally, the priority of the N_{Rep} CSI reports is based on the following:
1. A CSI report corresponding to one CSI reporting configuration for one cell may have higher priority compared with another CSI report corresponding to one other CSI reporting configuration for the same cell
2. CSI reports intended to one cell may have higher priority compared with other CSI reports intended to another cell
3. CSI reports may have higher priority based on the CSI report content, e.g., CSI reports carrying L1-RSRP information have higher priority
4. CSI reports may have higher priority based on their type, e.g., whether the CSI report is aperiodic, semi-persistent or periodic, and whether the report is sent via PUSCH or PUCCH, may impact the priority of the CSI report

In light of that, CSI reports may be prioritized as follows, where CSI reports with lower IDs have higher priority

$$P r {i}_{iCSI} ( y , k , c , s ) = 2 \cdot {N}_{c e l l s} \cdot {M}_{s} \cdot y + {N}_{c e l l s} \cdot {M}_{s} \cdot k + {M}_{s} \cdot c + s$$

s: CSI reporting configuration index, and Mₛ: Maximum number of CSI reporting configurations
c: Cell index, and N_{cells}: Number of serving cells
k: 0 for CSI reports carrying L1-RSRP or L1-SINR, 1 otherwise
y: 0 for aperiodic reports, 1 for semi-persistent reports on PUSCH, 2 for semi-persistent reports on PUCCH, 3 for periodic reports.

TABLE 1
Priority Reporting Levels for Part 2 CSI

Priority 0:
For CSI reports 1 to N_{Rep}, Group 0 CSI for CSI reports configured as ‘typeII-r16’ or
‘typeII-PortSelection-r16’; Part 2 wideband CSI for CSI reports configured otherwise
Priority 1:
Group 1 CSI for CSI report 1, if configured as ‘typeII-r16’ or ‘typeII-PortSelection-r16’;
Part 2 subband CSI of even subbands for CSI report 1, if configured otherwise
Priority 2:
Group 2 CSI for CSI report 1, if configured as ‘typeII-r16’ or ‘typeII-PortSelection-r16’;
Part 2 subband CSI of odd subbands for CSI report 1, if configured otherwise
Priority 3:
Group 1 CSI for CSI report 2, if configured as ‘typeII-r16’ or ‘typeII-PortSelection-r16’;
Part 2 subband CSI of even subbands for CSI report 2, if configured otherwise
Priority 4:
Group 2 CSI for CSI report 2, if configured as ‘typeII-r16’ or ‘typeII-PortSelection-r16’.
Part 2 subband CSI of odd subbands for CSI report 2, if configured otherwise
.
.
.
Priority 2N_{Rep} − 1:
Group 1 CSI for CSI report N_{Rep}, if configured as ‘typeII-r16’ or ‘typeII-PortSelection-
r16’; Part 2 subband CSI of even subbands for CSI report N_{Rep}, if configured otherwise
Priority 2N_{Rep}:
Group 2 CSI for CSI report N_{Rep}, if configured as ‘typeII-r16’ or ‘typeII-PortSelection-
r16’; Part 2 subband CSI of odd subbands for CSI report N_{Rep}, if configured otherwise

For triggering aperiodic CSI reporting on PUSCH, a UE needs to report the needed CSI information for the network using the CSI framework in NR Release 15. The triggering mechanism between a report setting and a resource setting can be summarized in Table 2 below.

TABLE 2
Triggering mechanism between a report
setting and a resource setting

| | | Periodic | | |
|---|---|---|---|---|
| | | CSI | | AP CSI |
| | | reporting | SP CSI reporting | Reporting |
| Time Domain | Periodic | RRC | MAC CE (PUCCH) | DCI |
| Behavior of | CSI-RS | configured | DCI (PUSCH) | |
| Resource | SP CSI- | Not | MAC CE (PUCCH) | DCI |
| Setting | RS | Supported | DCI (PUSCH) | |
| | AP CSI- | Not | Not Supported | DCI |
| | RS | Supported | | |

Moreover, in some embodiments,
All associated Resource Settings for a CSI Report Setting need to have same time domain behavior;
Periodic CSI-RS/IM resource and CSI reports are always assumed to be present and active once configured by RRC;
Aperiodic and semi-persistent CSI-RS/IM resources and CSI reports needs to be explicitly triggered or activated;
Aperiodic CSI-RS/IM resources and aperiodic CSI reports, the triggering is done jointly by transmitting a DCI Format 0-1; and
Semi-persistent CSI-RS/IM resources and semi-persistent CSI reports are independently activated.

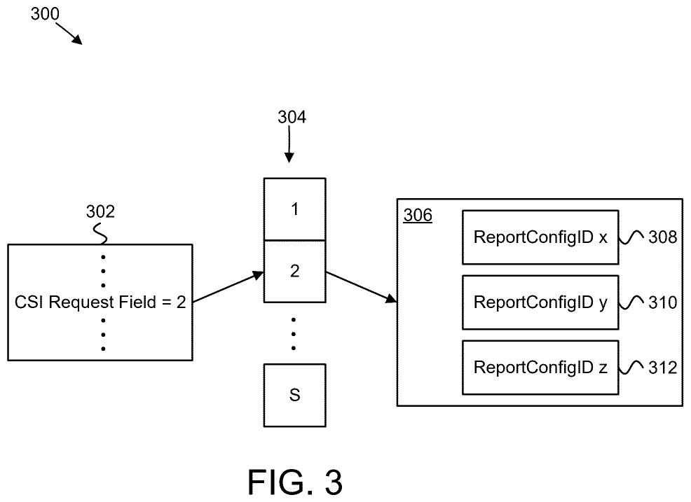

For aperiodic CSI-RS/IM resources and aperiodic CSI reports, the triggering is done jointly by transmitting a DCI Format 0-1. The DCI Format 0_1 contains a CSI request field (0 to 6 bits). A non-zero request field points to a so-called aperiodic trigger state configured by RRC (see FIG. 3). An aperiodic trigger state in turn is defined as a list of up to 16 aperiodic CSI Report Settings, identified by a CSI Report Setting ID for which the UE calculates simultaneously CSI and transmits it on the scheduled PUSCH transmission.

FIG. 3 is a diagram 300 illustrating one embodiment of an aperiodic trigger state defining a list of CSI report settings. Specifically, the diagram 300 includes a DCI format 0_1 302, a CSI request codepoint 304, and an aperiodic trigger state 2 306. Moreover, the aperiodic trigger state 2 includes a ReportConfigID x 308, a ReportConfigID y 310, and a ReportConfigID z 312. An aperiodic trigger state in turn is defined as a list of up to 16 aperiodic CSI Report Settings, identified by a CSI Report Setting ID for which the UE calculates simultaneously CSI and transmits it on the scheduled PUSCH transmission.

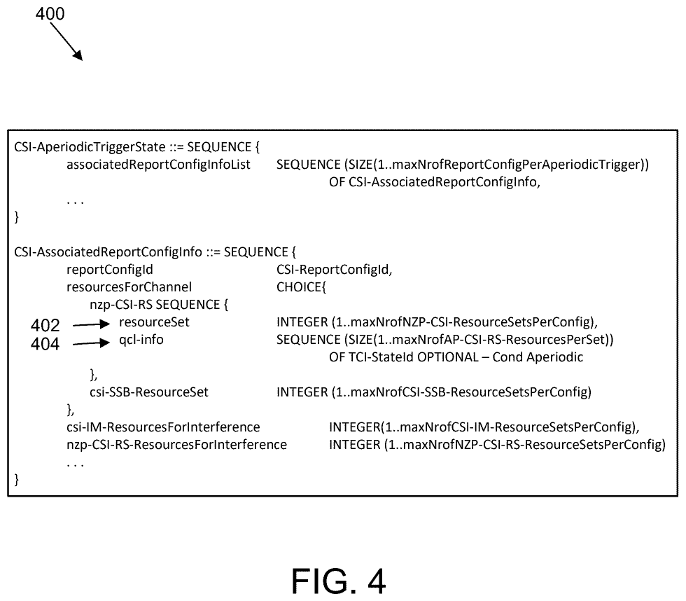

In one embodiment, if the CSI report setting is linked with aperiodic resource setting (e.g., may include multiple resource sets), the aperiodic NZP CSI-RS resource set for channel measurement, the aperiodic CSI-IM resource set (if used) and the aperiodic NZP CSI-RS resource set for interference management (“IM”) (if used) to use for a given CSI report setting are also included in the aperiodic trigger state definition, as shown in FIG. 4. For aperiodic NZP CSI-RS, QCL source may be configured in the aperiodic trigger state. The UE may assume that the resources used for the computation of the channel and interference can be processed with the same spatial filter e.g., quasi-co-located with respect to “QCL-TypeD.”

FIG. 4 is a code sample 400 illustrating one embodiment of the process by which an aperiodic trigger state indicates a resource set 402 and QCL information 404.

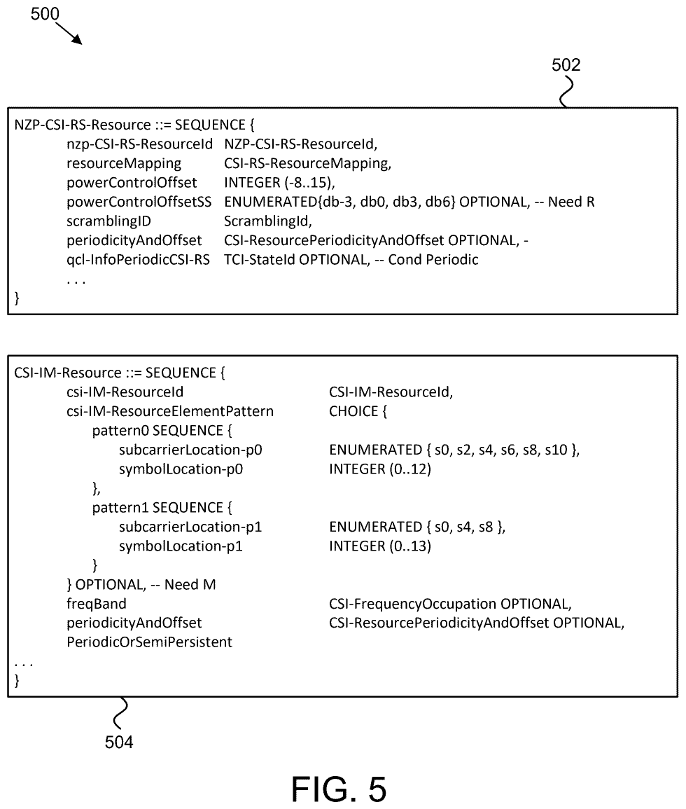

FIG. 5 is a code sample 500 illustrating one embodiment of an RRC configuration including a NZP-CSI-RS resource 502 and a CSI-IM-resource 504.

Table 3 shows the type of UL channels used for CSI reporting as a function of the CSI codebook type

TABLE 3
UL channels used for CSI reporting as
a function of the CSI codebook type

| | Periodic CSI | | AP CSI |
|---|---|---|---|
| | reporting | SP CSI reporting | reporting |
| Type I WB | PUCCH Format | PUCCH Format 2 | PUSCH |
| | 2, 3, 4 | PUSCH | |
| Type I SB | | PUCCH Format 3, 4 | PUSCH |
| | | PUSCH | |
| Type II WB | | PUCCH Format 3, 4 | PUSCH |
| | | PUSCH | |
| Type II SB | | PUSCH | PUSCH |
| Type II Part 1 | | PUCCH Format 3, 4 | |
| only | | | |

For aperiodic CSI reporting, in one embodiment, PUSCH-based reports are divided into two CSI parts: CSI Part1 and CSI Part 2. The reason for this is that the size of CSI payload varies significantly, and therefore a worst-case UCI payload size design would result in large overhead.

In one embodiment, CSI Part 1 has a fixed payload size (and can be decoded by the gNB without prior information) and contains the following:
Rank indicator (“RI”) (if reported), CSI-RS resource indicator (“CRI”) (if reported), and channel quality indicator (“CQI”) for the first codeword,
number of non-zero wideband amplitude coefficients per layer for Type II CSI feedback on PUSCH.

In one embodiment, CSI Part 2 has a variable payload size that can be derived from the CSI parameters in CSI Part 1 and contains PMI and the CQI for the second codeword when RI>4.

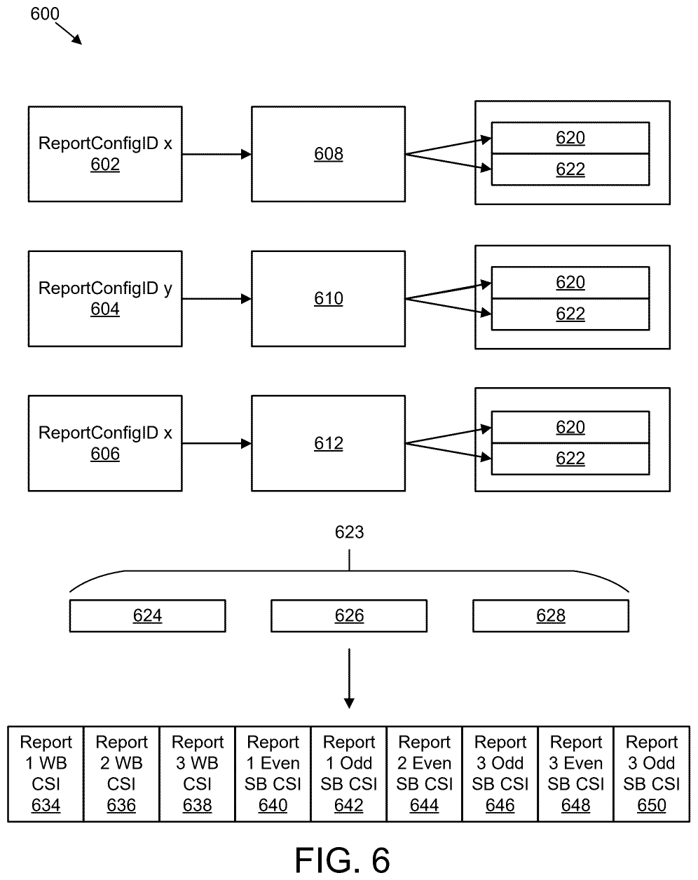

For example, if the aperiodic trigger state indicated by DCI format 0_1 defines 3 report settings x, y, and z, then the aperiodic CSI reporting for CSI part 2 will be ordered as indicated in FIG. 6.

FIG. 6 is a schematic block diagram 600 illustrating one embodiment of a partial CSI omission for PUSCH-based CSI. The diagram 600 includes a ReportConfigID x 602, a ReportConfigID y 604, and a ReportConfigID z 606. Moreover, the diagram 600 includes a first report 608 (e.g., requested quantities to be reported) corresponding to the ReportConfigID x 602, a second report 610 (e.g., requested quantities to be reported) corresponding to the ReportConfigID y 604, and a third report 612 (e.g., requested quantities to be reported) corresponding to the ReportConfigID z 606. Each of the first report 608, the second report 610, and the third report 612 includes a CSI part 1 620, and a CSI part 2 622. An ordering 623 of CSI part 2 across reports is CSI part 2 of the first report 624, CSI part 2 of the second report 626, and CSI part 2 of the third report 628. Moreover, the CSI part 2 reports may produce a report 1 WB CSI 634, a report 2 WB CSI 636, a report 3 WB CSI 638, a report 1 even SB CSI 640, a report 1 odd SB CSI 642, a report 2 even SB CSI 644, a report 2 odd SB CSI 646, a report 3 even SB CSI 648, and a report 3 odd SB CSI 650.

In various embodiments, CSI reports may be prioritized according to:
time-domain behavior and physical channel where more dynamic reports are given precedence over less dynamic reports and PUSCH has precedence over PUCCH;
CSI content where beam reports (e.g., L1-RSRP reporting) have priority over regular CSI reports;
a serving cell to which a CSI corresponds (e.g., for CA operation)-CSI corresponding to a PCell has priority over CSI corresponding to Scells; and/or
a report configuration identifier (e.g., reportConfigID).

As it relates to adjusting the number of feedback bits for deep learning-based methods, the number of feedback bits for AI-based methods depends on the size of the output of the NN block and the quantization method used for finding the final encoded data. For an AI-based model with a certain design, this value is fixed, and all input samples will have the same number of encoded bits.

There is a possibility of designing different models based on different factors including number of layers to feedback, bandwidth, and the load of the gNB which will lead to different number of feedback bits. However, for each of these designs (models) the number of feedback bits are fixed and not input sample dependent.

A method for construction, training, and sending the feedback data for a two-sided model that enables one AI-based structure to accommodate a different number of feedback bits for different input samples is discussed herein.

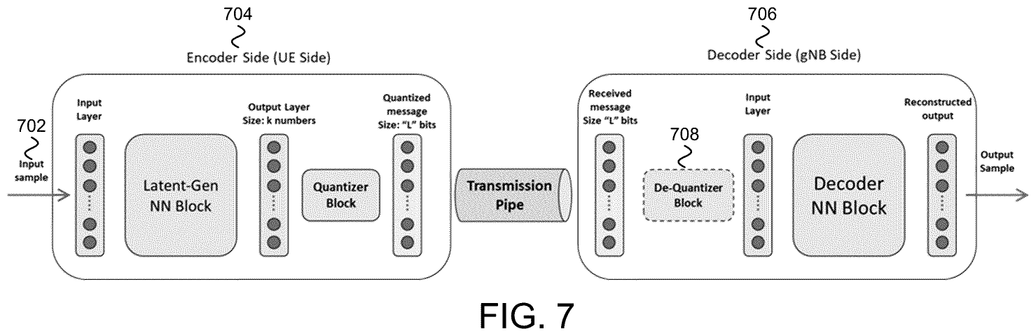

FIG. 7 depicts an embodiment of a typical structure of a two-sided model. As shown in FIG. 7, the high level structure of a typical two-sided model for sending an input sample 702 from a first node (e.g., encoder) 704 to a second node (e.g., gNB) 706 is depicted.

In FIG. 7, the de-quantization block 708 is marked as a dashed box since in some cases, for example, scaler quantization, this block might be not needed, and the received-message can be directly used as the input of the decoder NN block.

This model is trained using a training dataset D={(xᵢ,yᵢ), i={1, 2, . . . , M}} which consist of M samples, where each sample is pair representing the input and the expected output of the model. In some cases, the expected output could be the same as the input, so there could be no explicit mention of yᵢ in the training set.

The objective would be then to have the “output sample” of the model, i.e., ŷᵢ, to be as close as possible to the expected output yᵢ, for each input sample xᵢ. The loss function can be then to minimize the

$$loss = {\sum }_{i = 1}^{M} d i f f ( {\hat{y}}_{i} , {y}_{i} )$$

As explained before, with this design, the output of the encode-side is L bits for all input sample regardless of the sample itself.

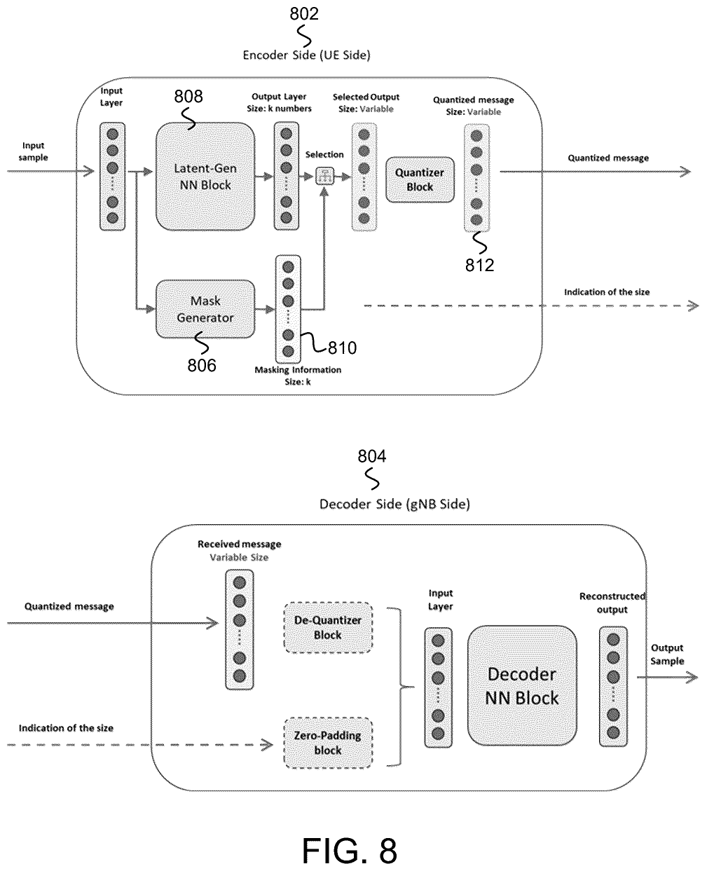

FIG. 8 depicts one embodiment of a modified structure of the encoder side 802 and the decoder side 804 of the two-sided model which support transmission of variable number of bits for different samples if needed.

In one embodiment, FIG. 8 shows the addition of the mask generator block 806. The mask generator block 806 receives the input sample and generates a vector, γ, of the same size of the output layer of the latent-gen block 808, i.e., size k. The vector γ is then used to select a few of the neurons of the output of the latent-gen block 808. For example, small entries (zero/close to zero) of γ will result in elimination of the corresponding entries of the output of the latent-gen block 808, i.e., those data do not need to be quantized/sent to the decoder-side 804 and decode side can simply put zero for those entries. In some examples, the entries/elements of the mask generator block output vector γ 810 is constrained to be either 0 or 1 or from the set {0, 1}. Due to this structure, the size of the quantized message 812 will be variable and will depend on the decision of the mask-generator block 806, which itself depends on the data.

In this structure, the encoder side 802 sends decoder assistance information regarding which entries have been quantized to the decoder side 804, including an indication of the size of the encoded data (that is quantized and sent to the decoder). In one implementation, and for general masking vector, this information would consist of an indication of the entries which are not masked, for example an ID can be assigned to each output layer neurons and send then corresponding IDs to the receiver.

In another implementation, the mask generator 806 can be designed such that the activated nodes become nested, i.e., a nested masking vector γ. Assuming that the output layer of the latent-gen NN block 808 has “k” neurons denoted by n₁, n₂, . . . , nₖ, by nested masking vector γ mean that:
If nⱼ gets activated for a particular sample (e.g., γ[j]=1), all nᵢ for i<j will be also activated (e.g., γ[i]=1 for i<j),
If nⱼ is not activated for a particular sample (e.g., γ[j]=0), all nᵢ for i>j will be also not-activated (e.g., γ[i]=0 for i>j).

In this embodiment, instead of sending the indication to the decoder 804 that of which entries are activated in the decoder assistance information, it is enough to send the number of active entries, e.g., [symbol] , and then decoder 804 will assume that the active samples are associated with n₁, n₂, . . . , [symbol] and can zero pad all other neurons. This scheme will save on the amount of feedback data needed for transmission of information regarding the active neurons. In one example, the number of active entries, e.g., [symbol] is indicated in a report or control information to the decode-side node (e.g., gNB), e.g., via the decoder assistance information.

The nested masking vector γ has the property that if the “i”th entry of the output layer is activated, all entries of the output layer corresponding to rows lower than “i” are also activated. So, the masking is nested, like the activated output layer can be for example: N₁, N₂, N₃, N₄ or N₁, N₂ or N₁, N₂, N₃, N₄, N₅, N₆. However, the masking vector γ can not activate neurons that are not sequential or consecutive starting from the first row (lowest entry) of the output layer, like N₁, N₃, N₅, N₇ is not possible.

This is an important property, because when the activation can happen only nested-wise it is enough for the decoder 804 to know how many neurons were active then it can find out which entries are non-zero (or alternatively, which entries are zeroed).

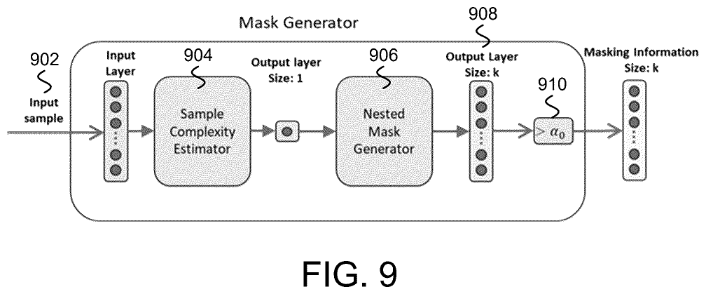

FIG. 9 depicts one embodiment to generate vector γ with nested property explained above. As shown in FIG. 9, the input data 902 is first mapped to a single number using a NN-block called sample-complexity estimator 904. The Nested Mask Generator block 906 receives a real number and the output 908 of the block is a vector γ of size k (k neurons) where all entries of γ are non-negative and the values of nⱼ should not be less than nᵢ if j<i.

This block could have additional property that the values of each neuron should get larger when the value of the input sample (the single real number) is getting larger. One possible implementation of this approach can be based on the network structure presented in M. Y. Z. J. Shao J, “Learning task-oriented communication for edge inference: An information bottleneck approach,” IEEE Journal on Selected Areas in Communication, vol. 1, pp. 197-211., 2021 Nov. 8 (incorporated herein by reference).

The output of the Nested Mask Generator block is then compared with threshold α₀ 910 to come to generate a masking information. The value of the threshold can be adjusted based on the required accuracy and the overhead cost. In some embodiments, the threshold can be adjusted using a configuration message coming from the decoder-side (e.g., gNB-side).

The internal structure of the sample-complexity estimator block 904 and the Nested Mask Generator block 906 can be application dependent.

The training objective in this model is first, as before, to minimize the expectation of the difference (or maximize the expectation of the similarity) between the output of the model and the expected output for the samples of the training set. Additionally, as this network has the possibility of having variable size output the objective would be to minimize the number of outputs (or the number of non-zero outputs) sent to the decoding-part.

One scheme for implementation of such objective is to minimize a loss function defined over the set of samples in the training dataset which is based on the weighted sum of at least one of the a) the negative mutual information between the vector representing the transmitted data (quantized message at the output of the encoder-part, or equivalently, the received quantized message (assuming no errors or channel errors are corrected) at the decoder-part) and the input samples and b) the negative of mutual information between the vector representing the transmitted data and the desired output of the model. C) the difference between the output of the model and the desired output of the model. The weights for different component can be designed based on the application. In some examples, some of the weights can be zero corresponding to the associated components not included in the loss function. In some examples, one of the components may have a weight of one. In one example, an additional scaled/weighted component may be included, such as the conditional entropy of the output layer of the latent-gen block (before selection and quantization) given the transmitted data i.e., quantized message at the output of the encoder-part, or equivalently, the received quantized message at the decoder-part which represents the uncertainty/distortion due to selection and quantization given the quantized message.

With this objective function the weight of the NN blocks will be selected such that it minimizes the number of transmitted bits while keeping the accuracy of the match between the output of the model and the desired output higher than a desired level. The weights used in the loss function and the threshold value used in generation of the masking information can be used to find the balance between the desired accuracy and overhead.

During the training the sample-complexity estimator block will learn to assigned higher values to samples which are more complex which later translates to larger number of active neurons in the Nested Mask Generator block. This property makes the model more flexible than two-sided models with fixed number of output layers.

In some examples, the quantizer may be a scalar quantizer. In one example, the output layer of the latent-gen block (after selection but before quantization) may be normalized (e.g., to zero-mean and/or unit variance) prior to quantization. In another example, the normalization may be performed after the selection block considering only the non-zero entries (activated neurons of the output layer). In some examples, the normalization values (e.g., mean and/or variance of the activated neurons of the output layers) are indicated to the decoder in a report, (e.g., second part CSI report). In another example, the quantized message comprises magnitude and phase of the output layer corresponding to the real part of the input samples, and the output layer corresponding to the imaginary part of the input samples. In this example, normalization may be applied such the maximum magnitude of the non-zero entries of the output layer (activated neurons of the output layer) post-selection is a constant such as the value 1.

In some examples, the quantizer may be a vector quantizer. In one example, the encoder may determine/select a subset of the vector quantizer codebook (e.g., every other entry, first half entries, second-half entries etc.) or may determine/select a subset of the codewords of a vector quantizer codebook and quantize the output layer according to the selected subset of quantizer codebook (codewords) thereby reducing the feedback size of the quantized message. In some examples, the encoder may send to the decoder an indication corresponding to the selected subset of quantizer codebook in a report (e.g., in first part CSI report). In some examples, the encoder may receive a message from the decoder indicating at least one subset of quantizer codebook to use for quantizing the output layer. The encoder may use the at least one subset of quantizer codebook to use for quantizing the output layer. In some examples, the encoder may send to the decoder an indication corresponding to the selected subset of quantizer codebook from the at least one subset of quantizer codebook (in case of more than one subsets) in a report (e.g., first part CSI report).

It is noted that the proposed two-sided structure is not only limited to the use-case of feeding back the channel information from the UE to the gNB, and it can be applied in other use-cases which needs transmission of information from one node to another while the amount of transmitted data should be kept at as low as possible.

In some implementations, the CSI report comprises two parts: a first part with a fixed size and a second part with a variable size, wherein a size of the second part is based on one or more parameters reported in the first part of the CSI report, and wherein an indication of the size of the quantized message is reported in the first part of the CSI report, such that the size of the second part of the CSI report is based on the size of the quantized message.

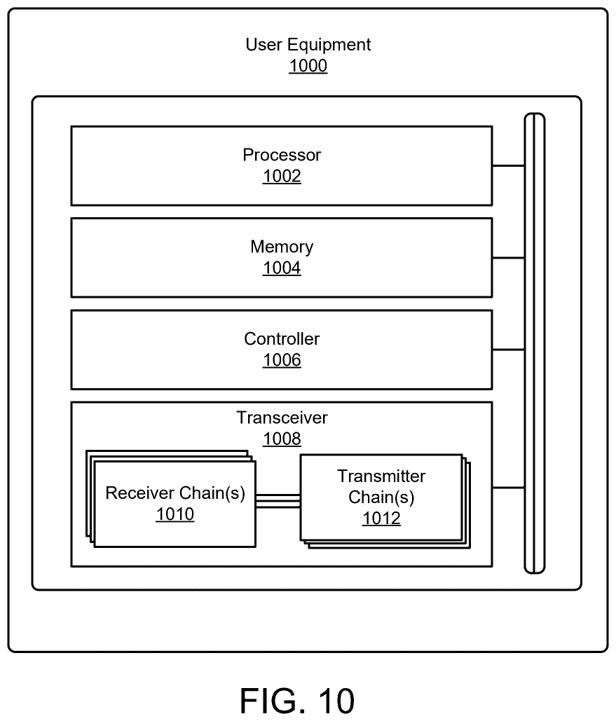

FIG. 10 illustrates an example of a UE 1000 in accordance with aspects of the present disclosure. The UE 1000 may include a processor 1002, a memory 1004, a controller 1006, and a transceiver 1008. The processor 1002, the memory 1004, the controller 1006, or the transceiver 1008, or various combinations thereof or various components thereof may be examples of means for performing various aspects of the present disclosure as described herein. These components may be coupled (e.g., operatively, communicatively, functionally, electronically, electrically) via one or more interfaces.

The processor 1002, the memory 1004, the controller 1006, or the transceiver 1008, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 1002 may include an intelligent hardware device (e.g., a general-purpose processor, a DSP, a CPU, an ASIC, an FPGA, or any combination thereof). In some implementations, the processor 1002 may be configured to operate the memory 1004. In some other implementations, the memory 1004 may be integrated into the processor 1002. The processor 1002 may be configured to execute computer-readable instructions stored in the memory 1004 to cause the UE 1000 to perform various functions of the present disclosure.

The memory 1004 may include volatile or non-volatile memory. The memory 1004 may store computer-readable, computer-executable code including instructions when executed by the processor 1002 cause the UE 1000 to perform various functions described herein. The code may be stored in a non-transitory computer-readable medium such the memory 1004 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 1002 and the memory 1004 coupled with the processor 1002 may be configured to cause the UE 1000 to perform one or more of the functions described herein (e.g., executing, by the processor 1002, instructions stored in the memory 1004). For example, the processor 1002 may support wireless communication at the UE 1000 in accordance with examples as disclosed herein. The UE 1000 may include an encoder to receive input data and transmit encoded output data from the encoder to a decoder comprised in a second apparatus. In one embodiment, the UE 1000 is configured to provide the input data to the encoder to generate the encoded output data, wherein a size of the encoded output data is dependent on the input data provided to the encoder and transmit the encoded output data to the decoder.

In one embodiment, the UE 1000 is configured to transmit decoder assistance information to the decoder, the decoder assistance information indicating the size of the encoded output data. In one embodiment, the UE 1000 is configured to transmit the encoded output data in a first message and the decoder assistance information in a second message.

In one embodiment, the encoder comprises at least one neural network model. In one embodiment, the UE 1000 is configured to receive information associated with the at least one neural network model, the information comprising a structure or weights of the at least one neural network model, information regarding a set of neural network models from a plurality of sets of neural network models, a set of neural network models based on an indication or configuration, or a combination thereof.

In one embodiment, the input data is based on channel data and comprises a representation of a measured channel matrix of a radio channel, a precoder for the radio channel, or a combination thereof. In one embodiment, the UE 1000 is provided with configuration parameters associated with the encoder, the configuration parameters comprising a threshold parameter for a size of the encoded output data, a target size of the encoded output data, a target accuracy of the encoded output data, an indication of an importance of an accuracy of the encoded output data, an overhead cost, or a combination thereof.

In one embodiment, the encoder comprises a neural network-based latent-generator. In one embodiment, the encoded output data is generated based on a latent representation of the input data generated using the neural network-based latent-generator and masking information.

In one embodiment, the encoder comprises a neural network-based mask generator and the masking information comprises a masking vector that is generated by providing the input data to the neural network-based mask generator. In one embodiment, the masking information relates to entries of the latent representation of the input data that are selected to generate the encoded output data.

In one embodiment, the masking information indicates a number of entries of the latent representation of the input data that are used to generate the encoded output data. In one embodiment, the UE 1000 is configured to transmit decoder assistance information comprising an indication of the encoded output data that are selected from a latent representation of the input data. In one embodiment, the encoded output data is further based on a scaler quantizer, a vector quantizer, or a combination thereof.

In one embodiment, the UE 1000 is configured to receive quantizer information defining parameters of the scaler quantizer, the vector quantizer, or a combination thereof. In one embodiment, the UE 1000 is configured to determine the size of the encoded output data by adjusting the parameters of the scaler quantizer or by selection of a subset of a codebook or codewords of a vector quantization scheme.

In one embodiment, the encoder is trained to minimize a loss function. In one embodiment, the loss function is based on a weighted sum of at least one component including mutual information between the input data and the encoded output data, negative of mutual information between the encoded output data and an expected target output, and difference between output of the encoder and the expected target output. In one embodiment, weights of the at least one component of the loss function are configurable, with a minimum weight being zero.

In one embodiment, the UE 1000 includes a decoder and is configured to receive encoded input data and decoder assistance information indicating a size of the encoded input data from a second apparatus and provide the encoded input data and the decoder assistance information to the decoder to generate decoded data.

The controller 1006 may manage input and output signals for the UE 1000. The controller 1006 may also manage peripherals not integrated into the UE 1000. In some implementations, the controller 1006 may utilize an operating system such as iOS®, ANDROID®, WINDOWS®, or other operating systems. In some implementations, the controller 1006 may be implemented as part of the processor 1002.

In some implementations, the UE 1000 may include at least one transceiver 1008. In some other implementations, the UE 1000 may have more than one transceiver 1008. The transceiver 1008 may represent a wireless transceiver. The transceiver 1008 may include one or more receiver chains 1010, one or more transmitter chains 1012, or a combination thereof.

A receiver chain 1010 may be configured to receive signals (e.g., control information, data, packets) over a wireless medium. For example, the receiver chain 1010 may include one or more antennas for receive the signal over the air or wireless medium. The receiver chain 1010 may include at least one amplifier (e.g., a low-noise amplifier (LNA)) configured to amplify the received signal. The receiver chain 1010 may include at least one demodulator configured to demodulate the receive signal and obtain the transmitted data by reversing the modulation technique applied during transmission of the signal. The receiver chain 1010 may include at least one decoder for decoding the processing the demodulated signal to receive the transmitted data.

A transmitter chain 1012 may be configured to generate and transmit signals (e.g., control information, data, packets). The transmitter chain 1012 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 1012 may also include at least one power amplifier configured to amplify the modulated signal to an appropriate power level suitable for transmission over the wireless medium. The transmitter chain 1012 may also include one or more antennas for transmitting the amplified signal into the air or wireless medium.

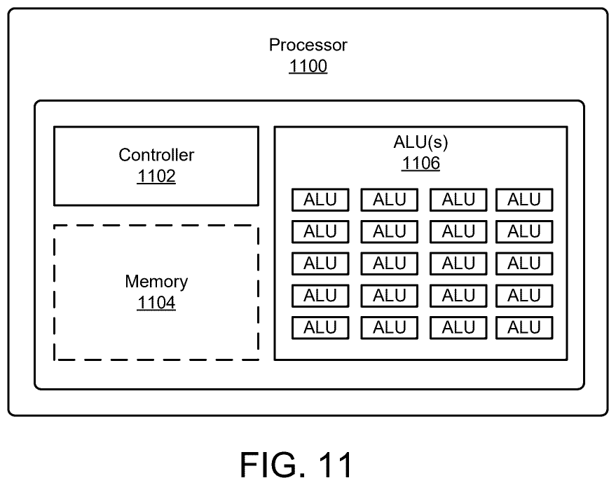

FIG. 11 illustrates an example of a processor 1100 in accordance with aspects of the present disclosure. The processor 1100 may be an example of a processor configured to perform various operations in accordance with examples as described herein. The processor 1100 may include a controller 1102 configured to perform various operations in accordance with examples as described herein. The processor 1100 may optionally include at least one memory 1104, which may be, for example, an L1/L2/L3 cache. Additionally, or alternatively, the processor 1100 may optionally include one or more arithmetic-logic units (ALUs) 1106. One or more of these components may be in electronic communication or otherwise coupled (e.g., operatively, communicatively, functionally, electronically, electrically) via one or more interfaces (e.g., buses).

The processor 1100 may be a processor chipset and include a protocol stack (e.g., a software stack) executed by the processor chipset to perform various operations (e.g., receiving, obtaining, retrieving, transmitting, outputting, forwarding, storing, determining, identifying, accessing, writing, reading) in accordance with examples as described herein. The processor chipset may include one or more cores, one or more caches (e.g., memory local to or included in the processor chipset (e.g., the processor 1100) or other memory (e.g., random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others).

The controller 1102 may be configured to manage and coordinate various operations (e.g., signaling, receiving, obtaining, retrieving, transmitting, outputting, forwarding, storing, determining, identifying, accessing, writing, reading) of the processor 1100 to cause the processor 1100 to support various operations in accordance with examples as described herein. For example, the controller 1102 may operate as a control unit of the processor 1100, generating control signals that manage the operation of various components of the processor 1100. These control signals include enabling or disabling functional units, selecting data paths, initiating memory access, and coordinating timing of operations.

The controller 1102 may be configured to fetch (e.g., obtain, retrieve, receive) instructions from the memory 1104 and determine subsequent instruction(s) to be executed to cause the processor 1100 to support various operations in accordance with examples as described herein. The controller 1102 may be configured to track memory address of instructions associated with the memory 1104. The controller 1102 may be configured to decode instructions to determine the operation to be performed and the operands involved. For example, the controller 1102 may be configured to interpret the instruction and determine control signals to be output to other components of the processor 1100 to cause the processor 1100 to support various operations in accordance with examples as described herein. Additionally, or alternatively, the controller 1102 may be configured to manage flow of data within the processor 1100. The controller 1102 may be configured to control transfer of data between registers, arithmetic logic units (ALUs), and other functional units of the processor 1100.

The memory 1104 may include one or more caches (e.g., memory local to or included in the processor 1100 or other memory, such RAM, ROM, DRAM, SDRAM, SRAM, MRAM, flash memory, etc. In some implementations, the memory 1104 may reside within or on a processor chipset (e.g., local to the processor 1100). In some other implementations, the memory 1104 may reside external to the processor chipset (e.g., remote to the processor 1100).

The memory 1104 may store computer-readable, computer-executable code including instructions that, when executed by the processor 1100, cause the processor 1100 to perform various functions described herein. The code may be stored in a non-transitory computer-readable medium such as system memory or another type of memory. The controller 1102 and/or the processor 1100 may be configured to execute computer-readable instructions stored in the memory 1104 to cause the processor 1100 to perform various functions. For example, the processor 1100 and/or the controller 1102 may be coupled with or to the memory 1104, the processor 1100, the controller 1102, and the memory 1104 may be configured to perform various functions described herein. In some examples, the processor 1100 may include multiple processors and the memory 1104 may include multiple memories. One or more of the multiple processors may be coupled with one or more of the multiple memories, which may, individually or collectively, be configured to perform various functions herein.

The one or more ALUs 1106 may be configured to support various operations in accordance with examples as described herein. In some implementations, the one or more ALUs 1106 may reside within or on a processor chipset (e.g., the processor 1100). In some other implementations, the one or more ALUs 1106 may reside external to the processor chipset (e.g., the processor 1100). One or more ALUs 1106 may perform one or more computations such as addition, subtraction, multiplication, and division on data. For example, one or more ALUs 1106 may receive input operands and an operation code, which determines an operation to be executed. One or more ALUs 1106 be configured with a variety of logical and arithmetic circuits, including adders, subtractors, shifters, and logic gates, to process and manipulate the data according to the operation. Additionally, or alternatively, the one or more ALUs 1106 may support logical operations such as AND, OR, exclusive-OR (XOR), not-OR (NOR), and not-AND (NAND), enabling the one or more ALUs 1106 to handle conditional operations, comparisons, and bitwise operations.

The processor 1100 may support wireless communication in accordance with examples as disclosed herein. The processor 1100 may include an encoder to receive input data and transmit encoded output data from the encoder to a decoder comprised in a second apparatus. In one embodiment, the processor 1100 is configured to provide the input data to the encoder to generate the encoded output data, wherein a size of the encoded output data is dependent on the input data provided to the encoder and transmit the encoded output data to the decoder.

In one embodiment, the processor 1100 is configured to transmit decoder assistance information to the decoder, the decoder assistance information indicating the size of the encoded output data. In one embodiment, the processor 1100 is configured to transmit the encoded output data in a first message and the decoder assistance information in a second message.

In one embodiment, the encoder comprises at least one neural network model. In one embodiment, the processor 1100 is configured to receive information associated with the at least one neural network model, the information comprising a structure or weights of the at least one neural network model, information regarding a set of neural network models from a plurality of sets of neural network models, a set of neural network models based on an indication or configuration, or a combination thereof.

In one embodiment, the input data is based on channel data and comprises a representation of a measured channel matrix of a radio channel, a precoder for the radio channel, or a combination thereof. In one embodiment, the processor 1100 is provided with configuration parameters associated with the encoder, the configuration parameters comprising a threshold parameter for a size of the encoded output data, a target size of the encoded output data, a target accuracy of the encoded output data, an indication of an importance of an accuracy of the encoded output data, an overhead cost, or a combination thereof.

In one embodiment, the encoder comprises a neural network-based latent-generator. In one embodiment, the encoded output data is generated based on a latent representation of the input data generated using the neural network-based latent-generator and masking information.

In one embodiment, the encoder comprises a neural network-based mask generator and the masking information comprises a masking vector that is generated by providing the input data to the neural network-based mask generator. In one embodiment, the masking information relates to entries of the latent representation of the input data that are selected to generate the encoded output data.

In one embodiment, the masking information indicates a number of entries of the latent representation of the input data that are used to generate the encoded output data. In one embodiment, the processor 1100 is configured to transmit decoder assistance information comprising an indication of the encoded output data that are selected from a latent representation of the input data. In one embodiment, the encoded output data is further based on a scaler quantizer, a vector quantizer, or a combination thereof.

In one embodiment, the processor 1100 is configured to receive quantizer information defining parameters of the scaler quantizer, the vector quantizer, or a combination thereof. In one embodiment, the processor 1100 is configured to determine the size of the encoded output data by adjusting the parameters of the scaler quantizer or by selection of a subset of a codebook or codewords of a vector quantization scheme.

In one embodiment, the encoder is trained to minimize a loss function. In one embodiment, the loss function is based on a weighted sum of at least one component including mutual information between the input data and the encoded output data, negative of mutual information between the encoded output data and an expected target output, and difference between output of the encoder machine learning model and the expected target output. In one embodiment, weights of the at least one component of the loss function are configurable, with a minimum weight being zero.

In one embodiment, the processor 1100 includes a decoder and is configured to receive encoded input data and decoder assistance information indicating a size of the encoded input data from a second apparatus and provide the encoded input data and the decoder assistance information to the decoder to generate decoded data.

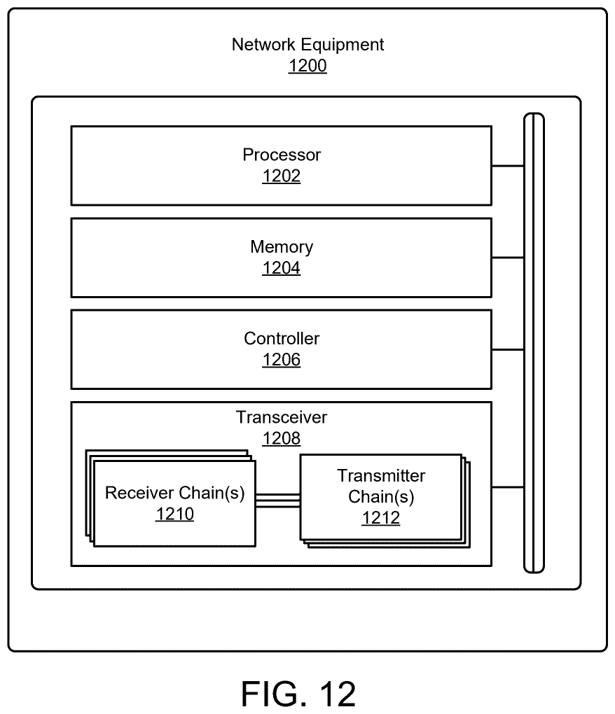

FIG. 12 illustrates an example of a NE 1200 in accordance with aspects of the present disclosure. The NE 1200 may include a processor 1202, a memory 1204, a controller 1206, and a transceiver 1208. The processor 1202, the memory 1204, the controller 1206, or the transceiver 1208, or various combinations thereof or various components thereof may be examples of means for performing various aspects of the present disclosure as described herein. These components may be coupled (e.g., operatively, communicatively, functionally, electronically, electrically) via one or more interfaces.

The processor 1202, the memory 1204, the controller 1206, or the transceiver 1208, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 1202 may include an intelligent hardware device (e.g., a general-purpose processor, a DSP, a CPU, an ASIC, an FPGA, or any combination thereof). In some implementations, the processor 1202 may be configured to operate the memory 1204. In some other implementations, the memory 1204 may be integrated into the processor 1202. The processor 1202 may be configured to execute computer-readable instructions stored in the memory 1204 to cause the NE 1200 to perform various functions of the present disclosure.

The memory 1204 may include volatile or non-volatile memory. The memory 1204 may store computer-readable, computer-executable code including instructions when executed by the processor 1202 cause the NE 1200 to perform various functions described herein. The code may be stored in a non-transitory computer-readable medium such the memory 1204 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 1202 and the memory 1204 coupled with the processor 1202 may be configured to cause the NE 1200 to perform one or more of the functions described herein (e.g., executing, by the processor 1202, instructions stored in the memory 1204). For example, the processor 1202 may support wireless communication at the NE 1200 in accordance with examples as disclosed herein. The NE 1200 may include an encoder to receive input data and transmit encoded output data from the encoder to a decoder comprised in a second apparatus. In one embodiment, the NE 1200 is configured to provide the input data to the encoder to generate the encoded output data, wherein a size of the encoded output data is dependent on the input data provided to the encoder and transmit the encoded output data to the decoder.

In one embodiment, the NE 1200 is configured to transmit decoder assistance information to the decoder, the decoder assistance information indicating the size of the encoded output data. In one embodiment, the NE 1200 is configured to transmit the encoded output data in a first message and the decoder assistance information in a second message.

In one embodiment, the encoder comprises at least one neural network model. In one embodiment, the NE 1200 is configured to receive information associated with the at least one neural network model, the information comprising a structure or weights of the at least one neural network model, information regarding a set of neural network models from a plurality of sets of neural network models, a set of neural network models based on an indication or configuration, or a combination thereof.

In one embodiment, the input data is based on channel data and comprises a representation of a measured channel matrix of a radio channel, a precoder for the radio channel, or a combination thereof. In one embodiment, the NE 1200 is provided with configuration parameters associated with the encoder, the configuration parameters comprising a threshold parameter for a size of the encoded output data, a target size of the encoded output data, a target accuracy of the encoded output data, an indication of an importance of an accuracy of the encoded output data, an overhead cost, or a combination thereof.

In one embodiment, the encoder comprises a neural network-based latent-generator. In one embodiment, the encoded output data is generated based on a latent representation of the input data generated using the neural network-based latent-generator and masking information.

In one embodiment, the encoder comprises a neural network-based mask generator and the masking information comprises a masking vector that is generated by providing the input data to the neural network-based mask generator. In one embodiment, the masking information relates to entries of the latent representation of the input data that are selected to generate the encoded output data.

In one embodiment, the masking information indicates a number of entries of the latent representation of the input data that are used to generate the encoded output data. In one embodiment, the NE 1200 is configured to transmit decoder assistance information comprising an indication of the encoded output data that are selected from a latent representation of the input data. In one embodiment, the encoded output data is further based on a scaler quantizer, a vector quantizer, or a combination thereof.

In one embodiment, the NE 1200 is configured to receive quantizer information defining parameters of the scaler quantizer, the vector quantizer, or a combination thereof. In one embodiment, the NE 1200 is configured to determine the size of the encoded output data by adjusting the parameters of the scaler quantizer or by selection of a subset of a codebook or codewords of a vector quantization scheme.

In one embodiment, the encoder is trained to minimize a loss function. In one embodiment, the loss function is based on a weighted sum of at least one component including mutual information between the input data and the encoded output data, negative of mutual information between the encoded output data and an expected target output, and difference between output of the encoder machine learning model and the expected target output. In one embodiment, weights of the at least one component of the loss function are configurable, with a minimum weight being zero.

In one embodiment, the NE 1200 includes a decoder and is configured to receive encoded input data and decoder assistance information indicating a size of the encoded input data from a second apparatus and provide the encoded input data and the decoder assistance information to the decoder to generate decoded data.

The controller 1206 may manage input and output signals for the NE 1200. The controller 1206 may also manage peripherals not integrated into the NE 1200. In some implementations, the controller 1206 may utilize an operating system such as iOS®, ANDROID®, WINDOWS®, or other operating systems. In some implementations, the controller 1206 may be implemented as part of the processor 1202.

In some implementations, the NE 1200 may include at least one transceiver 1208. In some other implementations, the NE 1200 may have more than one transceiver 1208. The transceiver 1208 may represent a wireless transceiver. The transceiver 1208 may include one or more receiver chains 1210, one or more transmitter chains 1212, or a combination thereof.

A receiver chain 1210 may be configured to receive signals (e.g., control information, data, packets) over a wireless medium. For example, the receiver chain 1210 may include one or more antennas for receive the signal over the air or wireless medium. The receiver chain 1210 may include at least one amplifier (e.g., a low-noise amplifier (LNA)) configured to amplify the received signal. The receiver chain 1210 may include at least one demodulator configured to demodulate the receive signal and obtain the transmitted data by reversing the modulation technique applied during transmission of the signal. The receiver chain 1210 may include at least one decoder for decoding the processing the demodulated signal to receive the transmitted data.

A transmitter chain 1212 may be configured to generate and transmit signals (e.g., control information, data, packets). The transmitter chain 1212 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 1212 may also include at least one power amplifier configured to amplify the modulated signal to an appropriate power level suitable for transmission over the wireless medium. The transmitter chain 1212 may also include one or more antennas for transmitting the amplified signal into the air or wireless medium.

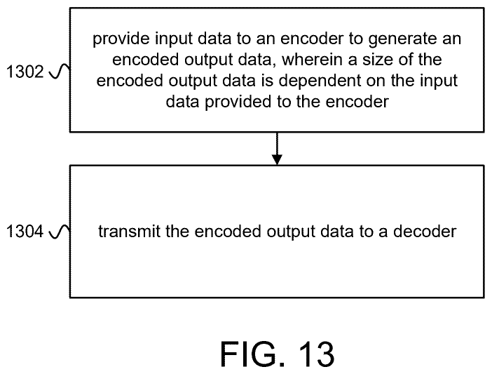

FIG. 13 illustrates a flowchart of a method in accordance with aspects of the present disclosure. The operations of the method may be implemented by a UE or a network equipment, e.g., a base station, as described herein. In some implementations, the UE or network equipment may execute a set of instructions to control the function elements of the UE or network equipment to perform the described functions.

At 1302, the method may provide input data to an encoder to generate an encoded output data, wherein a size of the encoded output data is dependent on the input data provided to the encoder. The operations of 1302 may be performed in accordance with examples as described herein. In some implementations, aspects of the operations of 1302 may be performed by a UE as described with reference to FIG. 10 or a network equipment as described in FIG. 12.

At 1304, the method may transmit the encoded output data to a decoder. The operations of 1304 may be performed in accordance with examples as described herein. In some implementations, aspects of the operations of 1304 may be performed by a UE as described with reference to FIG. 10 or a network equipment as described in FIG. 12.

It should be noted that the method described herein describes A possible implementation, and that the operations and the steps may be rearranged or otherwise modified and that other implementations are possible.

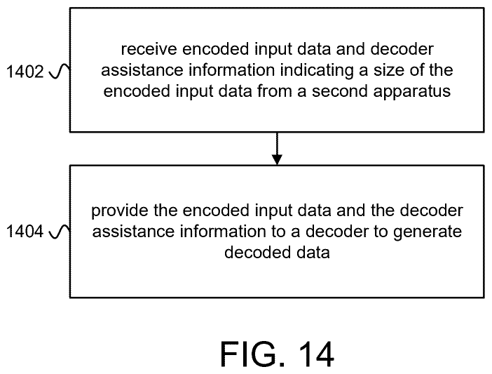

FIG. 14 illustrates a flowchart of a method in accordance with aspects of the present disclosure. The operations of the method may be implemented by a UE or a network equipment, e.g., a base station, as described herein. In some implementations, the UE or network equipment may execute a set of instructions to control the function elements of the UE or network equipment to perform the described functions.

At 1402, the method may receive encoded input data and decoder assistance information indicating a size of the encoded input data from a second apparatus. The operations of 1402 may be performed in accordance with examples as described herein. In some implementations, aspects of the operations of 1402 may be performed by a UE as described with reference to FIG. 10 or a network equipment as described in FIG. 12.

At 1404, the method may provide the encoded input data and the decoder assistance information to a decoder to generate decoded data. The operations of 1404 may be performed in accordance with examples as described herein. In some implementations, aspects of the operations of 1404 may be performed by a UE as described with reference to FIG. 10 or a network equipment as described in FIG. 12.

It should be noted that the method described herein describes A possible implementation, and that the operations and the steps may be rearranged or otherwise modified and that other implementations are possible.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. An apparatus for wireless communication, comprising:
at least one memory; and
at least one processor coupled with the at least one memory and configured to cause the apparatus, comprising an encoder to receive input data and transmit encoded output data from the encoder to a decoder comprised in a second apparatus to:
provide the input data to the encoder to generate the encoded output data, wherein a size of the encoded output data is dependent on the input data provided to the encoder; and
transmit the encoded output data to the decoder.

2. The apparatus of claim 1, wherein the at least one processor is configured to cause the apparatus to transmit decoder assistance information to the decoder, the decoder assistance information indicating the size of the encoded output data.

3. The apparatus of claim 2, wherein the at least one processor is configured to cause the apparatus to transmit the encoded output data in a first message and the decoder assistance information in a second message.

4. The apparatus of claim 1, wherein the encoder comprises at least one neural network model and wherein the at least one processor is configured to cause the apparatus to receive information associated with the at least one neural network model, the information comprising a structure or weights of the at least one neural network model, information regarding a set of neural network models from a plurality of sets of neural network models, a set of neural network models based on an indication or configuration, or a combination thereof.

5. The apparatus of claim 1, wherein the input data is based on channel data and comprises a representation of a measured channel matrix of a radio channel, a precoder for the radio channel, or a combination thereof.

6. The apparatus of claim 1, wherein the at least one processor is provided with configuration parameters associated with the encoder, the configuration parameters comprising a threshold parameter for a size of the encoded output data, a target size of the encoded output data, a target accuracy of the encoded output data, an indication of an importance of an accuracy of the encoded output data, an overhead cost, or a combination thereof.

7. The apparatus of claim 1, wherein the encoder comprises a neural network-based latent-generator.

8. The apparatus of claim 7, wherein the encoded output data is generated based on a latent representation of the input data generated using the neural network-based latent-generator and masking information.

9. The apparatus of claim 8, wherein the encoder comprises a neural network-based mask generator and the masking information comprises a masking vector that is generated by providing the input data to the neural network-based mask generator.

10. The apparatus of claim 8, wherein the masking information relates to entries of the latent representation of the input data that are selected to generate the encoded output data.

11. The apparatus of claim 8, wherein the masking information indicates a number of entries of the latent representation of the input data that are used to generate the encoded output data.

12. The apparatus of claim 8, wherein the at least one processor is configured to cause the apparatus to transmit decoder assistance information comprising an indication of the encoded output data that are selected from a latent representation of the input data.

13. The apparatus of claim 1, wherein the encoded output data is further based on a scaler quantizer, a vector quantizer, or a combination thereof.

14. The apparatus of claim 13, wherein the at least one processor is configured to cause the apparatus to receive quantizer information defining parameters of the scaler quantizer, the vector quantizer, or a combination thereof.

15. The apparatus of claim 14, wherein the at least one processor is configured to cause the apparatus to determine the size of the encoded output data by adjusting the parameters of the scaler quantizer or by selection of a subset of a codebook or codewords of a vector quantization scheme.

16. The apparatus of claim 1, wherein the encoder is trained to minimize a loss function, the loss function based on a weighted sum of at least one component comprising:
mutual information between the input data and the encoded output data;
negative of mutual information between the encoded output data and an expected target output; and
difference between output of the encoder and the expected target output.

17. The apparatus of claim 16, wherein weights of the at least one component of the loss function are configurable, with a minimum weight being zero.

18. A processor of an apparatus for wireless communication, the apparatus comprising an encoder to receive input data and transmit encoded output data from the encoder to a decoder comprised in a second apparatus, comprising:
at least one controller coupled with at least one memory and configured to cause the processor to:
provide the input data to the encoder to generate the encoded output data, wherein a size of the encoded output data is dependent on the input data provided to the encoder; and
transmit the encoded output data to the decoder.

19. A method of an apparatus for wireless communication, comprising:
encoding input data to generate encoded output data, wherein a size of the encoded output data is dependent on the input data; and
transmitting the encoded output data to a second apparatus.

20. An apparatus for wireless communication, comprising:
at least one memory; and
at least one processor coupled with the at least one memory and configured to cause the apparatus, comprising a decoder, to:
receive encoded input data and decoder assistance information indicating a size of the encoded input data from a second apparatus; and
provide the encoded input data and the decoder assistance information to the decoder to generate decoded data.
